(19) United States
(12) Patent Application Publication
(10) Pub. No.: US 2023/0253044 A1
(43) Pub. Date: Aug. 10, 2023

(54) THREE-DIMENSIONAL NON-VOLATILE MEMORY DEVICE

(71) Applicant: SAMSUNG ELECTRONICS CO., LTD., Suwon-si (KR)

(72) Inventors: Beakhyung CHO, Suwon-si (KR); Daeseok BYEON, Suwon-si (KR)

(73) Assignee: SAMSUNG ELECTRONICS CO., LTD., Suwon-si (KR)

(21) Appl. No.: 18/093,375

(22) Filed: Jan. 5, 2023

(30) Foreign Application Priority Data
Feb. 4, 2022 (KR) 10-2022-0015074
Jun. 29, 2022 (KR) 10-2022-0079993

(51) Int. Cl. G11C 16/04; G11C 16/08; H10B 41/10; H10B 41/35; H10B 41/40; H10B 41/27; H10B 43/10; H10B 43/27; H10B 43/35; H10B 43/40

(52) U.S. Cl. CPC G11C 16/0483; G11C 16/08; H10B 41/10; H10B 41/35; H10B 41/40; H10B 41/27; H10B 43/10; H10B 43/27; H10B 43/35; H10B 43/40

(57) ABSTRACT

In some embodiments, a non-volatile memory device includes a first semiconductor chip and a second semiconductor chip. The first semiconductor chip includes a memory cell array, a first upper bonding pad, a second upper bonding pad, and an upper dummy bonding pad between the first upper bonding pad and the second upper bonding pad. The second semiconductor chip is coupled to the first semiconductor chip in a vertical direction and includes a first lower bonding pad, a second lower bonding pad, a lower dummy bonding pad, and a peripheral circuit coupled to the first lower bonding pad and the second lower bonding pad. The first bonding pads are configured to transfer a first voltage between the first semiconductor chip and the second semiconductor chip. The second bonding pads are configured to transfer a second voltage between the first semiconductor chip and the second semiconductor chip.

### CROSS-REFERENCE TO RELATED APPLICATIONS

This application claims priority to Korean Patent Application No. 10-2022-0015074, filed on Feb. 4, 2022, and Korean Patent Application No. 10-2022-0079993, filed on Jun. 29, 2022, in the Korean Intellectual Property Office, the disclosures of which are incorporated by reference herein in their entireties.

### BACKGROUND

### 1. Field

The present disclosure relates to a memory device, and more particularly, to a three-dimensional (3D) non-volatile memory device obtained by connecting a first chip, in which memory cells are arranged, to a second chip, in which a peripheral circuit is arranged, in a bonding manner.

### 2. Description of Related Art

Related memory devices may be used to store data and may be classified into volatile memory devices and non-volatile memory devices. According to the demand for the capacity increase and size reduction of non-volatile memory devices, related 3-dimensional memory devices, in which a memory cell array is arranged vertically with respect to a peripheral circuit, have been developed. In chip-to-chip (C2C) memory devices obtained by connecting a first chip, in which memory cells arranged, to a second chip, in which a peripheral circuit is arranged, in a bonding manner, voltages may be transferred between the first chip and the second chip through bonding pads arranged on one surface of the first chip and bonding pads arranged in one surface of the second chip. Here, due to the reduction in the design rule according to the demand for the size reduction of memory devices, there may occur an issue of the metal reliability of high-voltage bonding pads and connection wiring lines related thereto for transferring high voltages between the first chip and the second chip.

### SUMMARY

The present disclosure provides a non-volatile memory device capable of improving the metal reliability of high-voltage bonding pads and connection wiring lines related thereto.

According to an aspect of the present disclosure, a non-volatile memory device includes a first semiconductor chip and a second semiconductor chip. The first semiconductor chip includes a memory cell array, a first upper bonding pad, a second upper bonding pad, and an upper dummy bonding pad between the first upper bonding pad and the second upper bonding pad. The second semiconductor chip is coupled to the first semiconductor chip in a vertical direction and includes a first lower bonding pad corresponding to the first upper bonding pad, a second lower bonding pad corresponding to the second upper bonding pad, a lower dummy bonding pad corresponding to the upper dummy bonding pad, and a peripheral circuit coupled to the first lower bonding pad and the second lower bonding pad. The first upper bonding pad and the first lower bonding pad are configured to transfer a first voltage between the first semiconductor chip and the second semiconductor chip. The second upper bonding pad and the second lower bonding pad are configured to transfer a second voltage between the first semiconductor chip and the second semiconductor chip, a second level of the second voltage being higher than a first level of the first voltage.

According to an aspect of the present disclosure, a non-volatile memory device includes a first semiconductor chip and a second semiconductor chip. The first semiconductor chip includes a memory cell array, a first upper bonding pad having a first width in a first direction, and a second upper bonding pad having a second width in the first direction. The second width is greater than the first width. The second semiconductor chip is coupled to the first semiconductor chip in a vertical direction and includes a first lower bonding pad corresponding to the first upper bonding pad, a second lower bonding pad corresponding to the second upper bonding pad, and a peripheral circuit coupled to the first lower bonding pad and the second lower bonding pad. The first upper bonding pad and the first lower bonding pad are configured to transfer a first voltage between the first semiconductor chip and the second semiconductor chip. The second upper bonding pad and the second lower bonding pad are configured to transfer a second voltage between the first semiconductor chip and the second semiconductor chip. The second level of the second voltage is higher than a first level of the first voltage.

According to an aspect of the present disclosure, a non-volatile memory device includes a first semiconductor chip and a second semiconductor chip. The first semiconductor chip includes a first cell region and a second cell region that are adjacent to each other in a first direction. The first cell region includes a first memory cell array, a first upper bonding pad having a first width in the first direction, and a second upper bonding pad having a second width in the first direction that is greater than the first width of the first upper bonding pad. The second cell region includes a second memory cell array and a third upper bonding pad. The second semiconductor chip is coupled to the first semiconductor chip in a vertical direction and includes a first peripheral region and a second peripheral region. The first peripheral region includes a first lower bonding pad corresponding to the first upper bonding pad, a second lower bonding pad corresponding to the second upper bonding pad, and a first peripheral circuit coupled to the first lower bonding pad and the second lower bonding pad, and the second peripheral region includes a third lower bonding pad corresponding to the third upper bonding pad and a second peripheral circuit coupled to the third lower bonding pad. The first semiconductor chip further includes a metal layer connecting the second upper bonding pad to the third upper bonding pad. The first memory cell array is configured to receive a first voltage from the first peripheral circuit through the first upper bonding pad and the first lower bonding pad. The first peripheral circuit is configured to receive a second voltage from the second peripheral circuit through the second upper bonding pad, the third upper bonding pad, the second lower bonding pad, the third lower bonding pad, and the metal layer. A second level of the second voltage is higher voltage level than a first level of the first voltage.

### BRIEF DESCRIPTION OF DRAWINGS

The above and other aspects, features, and advantages of certain embodiments of the present disclosure will be more apparent from the following description taken in conjunction with the accompanying drawings in which:

FIG. 1 is a block diagram illustrating a memory device, according to an embodiment;

FIG. 2 is a circuit diagram illustrating a memory block, according to an embodiment;

FIGS. 3A and 3B are perspective views each illustrating a memory block, according to some embodiments;

FIG. 4 illustrates a memory device having a bonding vertical NAND (B-VNAND) structure, according to an embodiment;

FIG. 5 illustrates a memory device, according to an embodiment;

FIG. 6 is a cross-sectional view illustrating an example of a first region of the memory device of FIG. 5, according to an embodiment;

FIG. 7 is a cross-sectional view illustrating an example of a second region of the memory device of FIG. 5, according to an embodiment;

FIG. 8 illustrates a memory device, according to an embodiment;

FIG. 9 is a cross-sectional view illustrating an example of a second region of the memory device of FIG. 8, according to an embodiment;

FIG. 10 illustrates a memory device, according to an embodiment;

FIGS. 11A and 11B are plan views respectively illustrating examples of bonding pads arranged in a first region of the memory device of FIG. 10, according to some embodiments;

FIGS. 12A to 12C are plan views respectively illustrating examples of bonding pads arranged in a second region of the memory device of FIG. 10, according to some embodiments;

FIGS. 13A to 13D are plan views respectively illustrating examples of bonding pads arranged in a third region of the memory device of FIG. 10, according to some embodiments;

FIGS. 14 to 17 are cross-sectional views respectively illustrating examples of the memory device of FIG. 10, according to some embodiments;

FIG. 18 is a cross-sectional view of a memory device having a B-VNAND structure, according to an embodiment; and

FIG. 19 is a block diagram illustrating a solid-state drive (SSD) system, to which a memory device, according to an embodiment.

### DETAILED DESCRIPTION

The following description with reference to the accompanying drawings is provided to assist in a comprehensive understanding of embodiments of the present disclosure defined by the claims and their equivalents. The embodiments described herein are example embodiments. Various specific details are included to assist in understanding, but these details are considered Various specific details are included to assist in understanding, but these details are considered to be exemplary only. Therefore, those of ordinary skill in the art will recognize that various changes and modifications of the embodiments described herein can be made without departing from the scope and spirit of the disclosure. In addition, descriptions of well-known functions and structures are omitted for clarity and conciseness.

With regard to the description of the drawings, similar reference numerals may be used to refer to similar or related elements. It is to be understood that a singular form of a noun corresponding to an item may include one or more of the things, unless the relevant context clearly indicates otherwise. As used herein, each of such phrases as “A or B,” “at least one of A and B,” “at least one of A or B,” “A, B, or C,” “at least one of A, B, and C,” and “at least one of A, B, or C,” may include any one of, or all possible combinations of the items enumerated together in a corresponding one of the phrases. As used herein, such terms as “1st” and “2nd,” or “first” and “second” may be used to simply distinguish a corresponding component from another, and does not limit the components in other aspect (e.g., importance or order). It is to be understood that if an element (e.g., a first element) is referred to, with or without the term “operatively” or “communicatively”, as “coupled with,” “coupled to,” “connected with,” or “connected to” another element (e.g., a second element), it means that the element may be coupled with the other element directly (e.g., wired), wirelessly, or via a third element.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

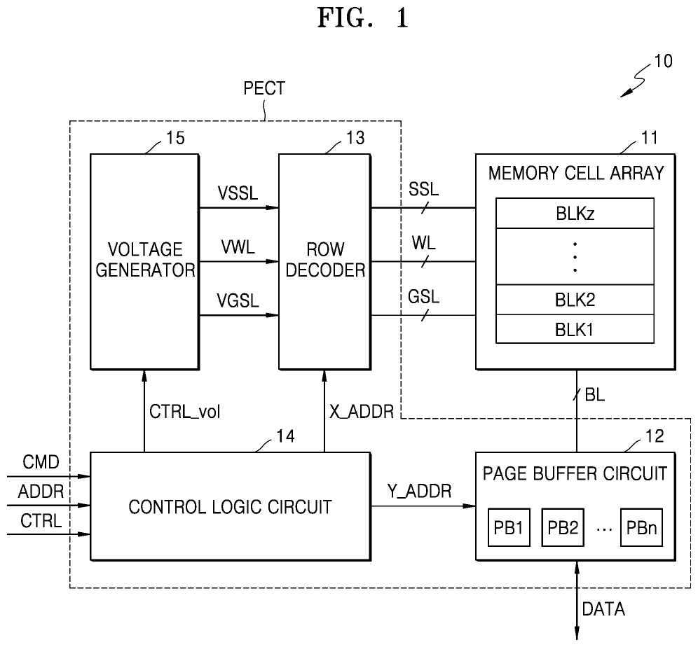

FIG. 1 is a block diagram illustrating a memory device according to an embodiment.

Referring to FIG. 1, a memory device 10 may include a memory cell array 11 and a peripheral circuit PECT, and the peripheral circuit PECT may include a page buffer circuit 12, a row decoder 13, a control logic circuit 14, and a voltage generator 15. In some embodiments, the peripheral circuit PECT may further include a data input-output circuit, an input-output interface, or the like (not shown). Alternatively or additionally, the peripheral circuit PECT may further include a pre-decoder, a temperature sensor, a command decoder, an address decoder, or the like. As used herein, the memory device 10 may refer to a “non-volatile memory device”.

The memory cell array 11 may include a plurality of memory blocks BLK1 to BLKz (hereinafter “BLK”, generally), where z is a positive integer. Each of the plurality of memory blocks BLK may include a plurality of memory cells. The memory cell array 11 may be connected to the page buffer circuit 12 through bit lines BL, and may be connected to the row decoder 13 through word lines WL, string select lines SSL, and ground select lines GSL. For example, the memory cells may include flash memory cells. Hereinafter, embodiments of the present disclosure will be described by taking examples in which the memory cells include NAND flash memory cells. However, the present disclosure is not limited thereto, and in some embodiments, the memory cells may include resistive memory cells such as resistive random access memory (ReRAM) cells, phase-change RAM (PRAM) cells, or magnetic RAM (MRAM) cells.

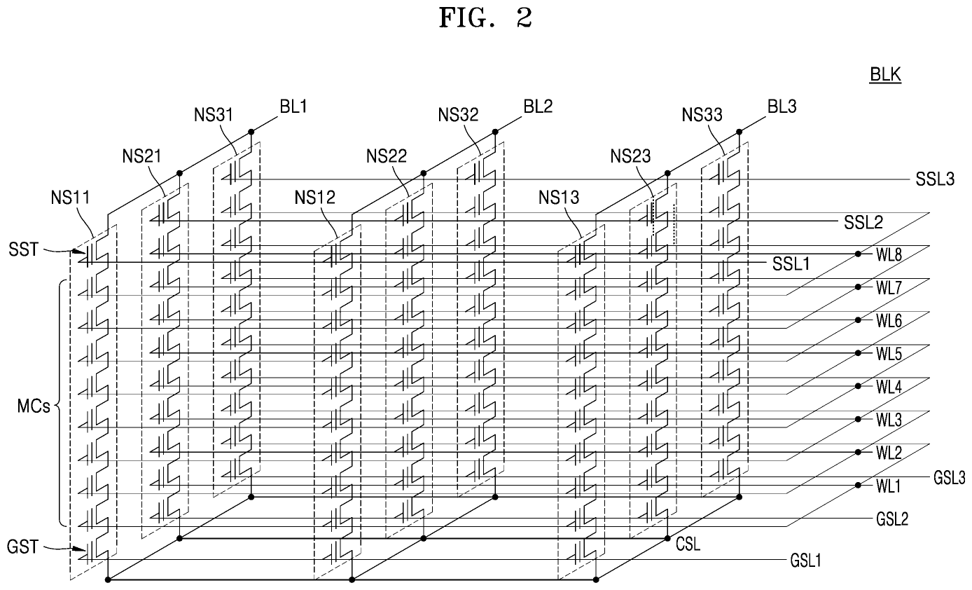

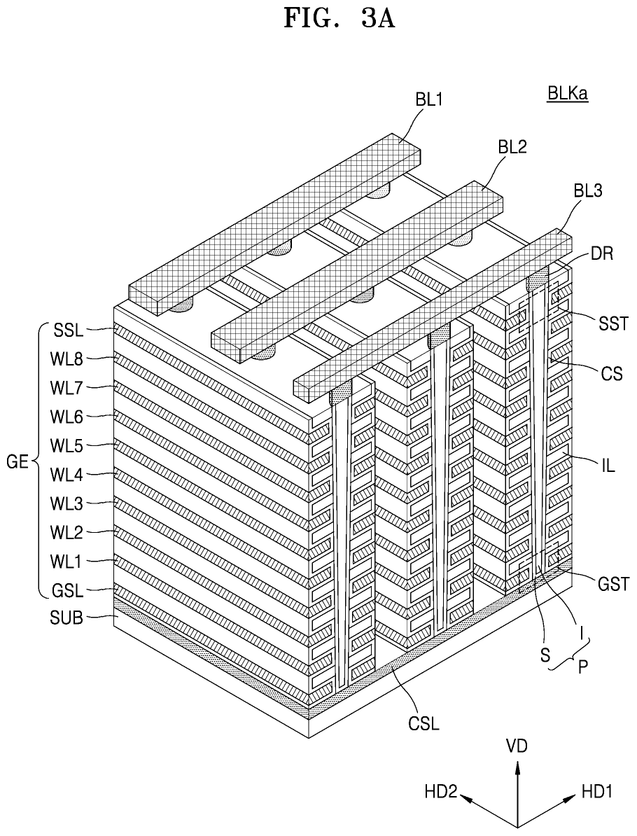

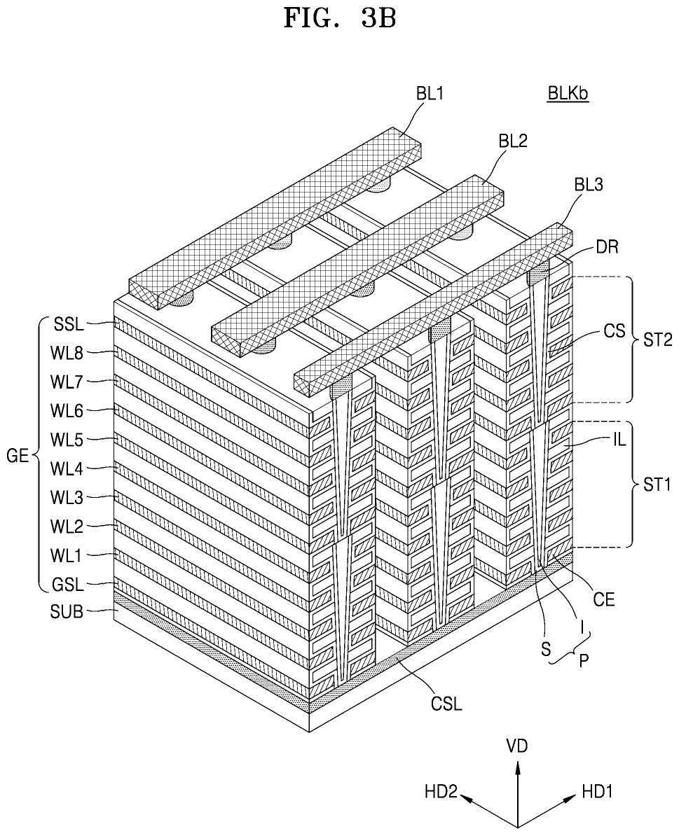

In some embodiments, the memory cell array 11 may include a 3-dimensional memory cell array, the 3-dimensional memory cell array may include a plurality of NAND strings, and each of the plurality of NAND strings may include memory cells respectively connected to word lines vertically stacked over a substrate. This will be described below with reference to FIGS. 2 to 3B. U.S. Pat. Nos. 7,679,133 8,553,466, 8,654,587, 8,559,235, and 9,536,970, the disclosures of which are incorporated by reference herein in their entireties, disclose appropriate configurations of a 3-dimensional memory array, in which the 3-dimensional memory array includes a plurality of levels and word lines and/or bit lines are shared between the plurality of levels. However, the present disclosure is not limited thereto, and in some embodiments, the memory cell array 11 may include a 2-dimensional memory cell array, and the 2-dimensional memory cell array may include a plurality of NAND strings arranged in row and column directions.

The page buffer circuit 12 may include a plurality of page buffers PB1 to PBn (hereinafter “PB”, generally), where n is a positive integer. Each of the plurality of page buffers PB may be connected (coupled) to the memory cells of the memory cell array 11 through a bit line corresponding thereto. The page buffer circuit 12 may select at least one of the bit lines BL according to control by the control logic circuit 14. For example, the page buffer circuit 12 may select some of the bit lines BL, in response to a column address Y_ADDR received from the control logic circuit 14.

Each of the plurality of page buffers PB may operate as a write driver or a sense amplifier. For example, in a program operation, each of the plurality of page buffers PB may store data DATA in a memory cell by applying a voltage corresponding to the data DATA to be programmed to a bit line. For example, in a program-verify operation or a read operation, each of the plurality of page buffers PB may sense the programmed data DATA by sensing a current or a voltage through a bit line.

The control logic circuit 14 may output various control signals, for example, a voltage control signal CTRL_vol, a row address X_ADDR, and a column address Y_ADDR, for programming data into the memory cell array 11, reading data from the memory cell array 11, or erasing data stored in the memory cell array 11, based on a command CMD, an address ADDR, and a control signal CTRL. Thus, the control logic circuit 14 may take overall control of various operations in the memory device 10. For example, the control logic circuit 14 may receive the command CMD, the address ADDR, and the control signal CTRL from a memory controller.

The voltage generator 15 may generate various voltages for performing program, read, and erase operations on the memory cell array 11, based on the voltage control signal CTRL_vol. For example, the voltage generator 15 may generate a word line voltage VWL, such as, but not limited to, a program voltage, a read voltage, a pass voltage, an erase-verify voltage, a program-verify voltage, or the like. Alternatively or additionally, the voltage generator 15 may further generate a string select line voltage VSSL and a ground select line voltage VGSL, based on the voltage control signal CTRL_vol.

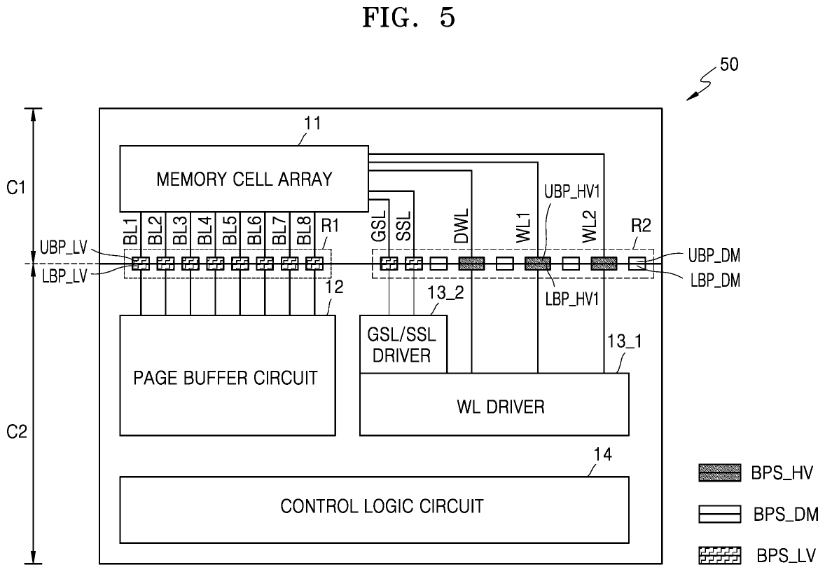

The row decoder 13 may select one of the plurality of memory blocks BLK, select one of the word lines WL of the selected memory block, and select one of a plurality of string select lines SSL, in response to the row address X_ADDR received from the control logic circuit 14. For example, the row decoder 13, during a program operation, may apply a program voltage and a program-verify voltage to the selected word line, and during a read operation, may apply a read voltage to the selected word line. For example, the row decoder 13 may include a word line driver (e.g., 13_1 in FIG. 5) and a ground select line/string select line driver (e.g., 13_2 in FIG. 5). For example, the row decoder 13 may further include a pass transistor circuit, a block decoder, and a drive signal line decoder.

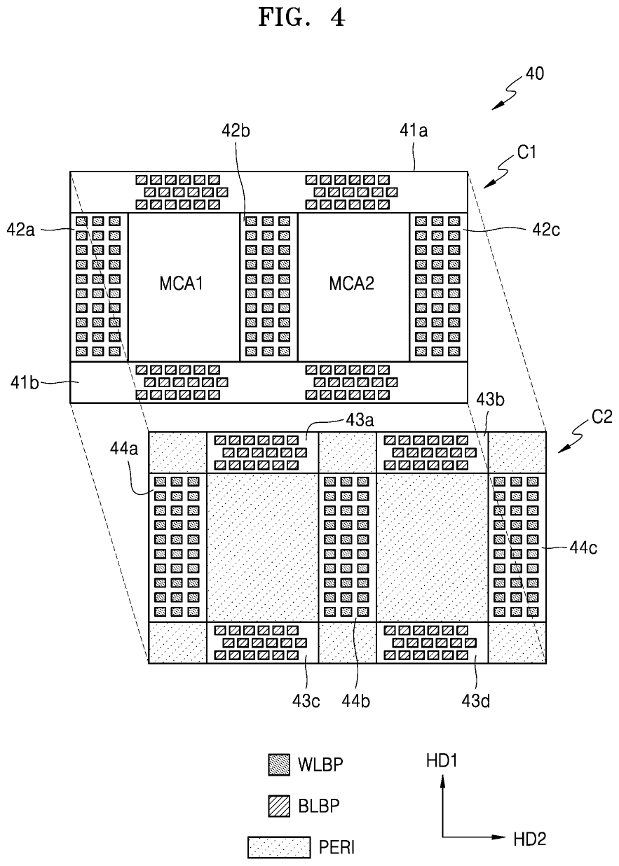

According to some embodiments, the memory cell array 11 may be arranged in a first semiconductor chip (e.g., C1 in FIG. 4), and the peripheral circuit PECT may be arranged in a second semiconductor chip (e.g., C2 in FIG. 4). The memory device 10 having such an arrangement structure may be referred to as a Bonding Vertical NAND (B-VNAND) type memory device or a chip-to-chip (C2C) bonding-structure memory device. According to a C2C bonding structure, a horizontal area of the memory device 10 may be effectively reduced, and a degree of integration of the memory device 10 may be improved. According to some embodiments, the first semiconductor chip may be referred to as a first semiconductor layer, a first wafer, a first chip, a first die, an upper semiconductor layer, an upper wafer, an upper chip, or an upper semiconductor chip. According to some embodiments, the second semiconductor chip may be referred to as a second semiconductor layer, a second wafer, a second chip, a second die, a lower semiconductor layer, a lower wafer, a lower chip, or a lower semiconductor chip.

In some embodiments, the first semiconductor chip may include upper bonding pads connected to the memory cell array 11, the second semiconductor chip may include lower bonding pads connected to the peripheral circuit PECT, and the memory cell array 11 may be electrically connected to the peripheral circuit PECT through bonding between the upper bonding pads and the lower bonding pads. Here, the word lines WL, the string select lines SSL, the ground select lines GSL, and the bit lines BL may be connected to the upper bonding pads and the lower bonding pads.

In some embodiments, voltages applied to the word lines WL, the string select lines SSL, the ground select lines GSL, and the bit lines BL may be different from each other. For example, a low voltage having a relatively low voltage level may be applied to the string select lines SSL, the ground select lines GSL, and the bit lines BL, and a high voltage having a relatively high voltage level may be applied to the word lines WL. The voltages applied to the word lines WL, the string select lines SSL, the ground select lines GSL, and the bit lines BL may be different from each other according to types of memory operations.

In a program operation, a turn-on voltage may be applied to a selected string select line from among the string select lines SSL, a program voltage may be applied to a selected word line from among the word lines WL, and a pass voltage may be applied to non-selected word lines from among the word lines WL. For example, the voltage level of the program voltage may be higher than the voltage level of the pass voltage. For example, although the voltage level of the pass voltage may be higher than the voltage level of the turn-on voltage, the present disclosure is not limited thereto.

In a read operation, the turn-on voltage may be applied to the selected string select line from among the string select lines SSL and to the ground select line GSL, a target voltage may be applied to the selected word line from among the word lines WL, and a read voltage may be applied to the non-selected word lines from among the word lines WL. For example, the voltage level of the read voltage may be higher than the voltage level of the target voltage. For example, although the voltage level of the target voltage may be higher the voltage level of the turn-on voltage, the present disclosure is not limited thereto.

As described above, a first voltage, that is, a low voltage, which has a relatively low voltage level, may be applied to the string select lines SSL, the ground select lines GSL, and the bit lines BL, and a second voltage, that is, a high voltage, which has a relatively high voltage level, may be applied to the word lines WL. In some embodiments, the size or width of each of the upper bonding pads and the lower bonding pads, to which the word lines WL are respectively connected, may be greater than the size or width of each of the upper bonding pads and the lower bonding pads, to which the string select lines SSL, the ground select lines GSL, and the bit lines BL are connected. In some embodiments, the pitch of each of the upper bonding pads and the lower bonding pads, to which the word lines WL are respectively connected, may be greater than the pitch of each of the upper bonding pads and the lower bonding pads, to which the string select lines SSL, the ground select lines GSL, and the bit lines BL are connected. In some embodiments, at least one upper dummy bonding pad may be arranged adjacent to the upper bonding pads, to which the word lines WL are respectively connected, and at least one lower dummy bonding pad may be arranged adjacent to the lower bonding pads, to which the word lines WL are respectively connected.

FIG. 2 is a circuit diagram illustrating a memory block BLK according to an embodiment.

Referring to FIG. 2, the memory block BLK may correspond to one of the plurality of memory blocks BLK of FIG. 1. The memory block BLK may include NAND strings NS11 to NS33, and each NAND string (e.g., NS11) may include a string select transistor SST, a plurality of memory cells MCs, and a ground select transistor GST, which are connected in series. The string select and ground select transistors SST and GST and the memory cells MCs, which are included in each NAND string, may form a structure stacked in a vertical direction over a substrate.

Bit lines BL1 to BL3 may extend in a first direction or a first horizontal direction, and word lines WL1 to WL8 may extend in a second direction or a second horizontal direction. As used herein, the first horizontal direction indicates the first direction, and the second horizontal direction indicates the second direction. The NAND strings NS11, NS21, and NS31 may be arranged between a first bit line BL1 and a common source line CSL, the NAND strings NS12, NS22, and NS32 may be arranged between a second bit line BL2 and the common source line CSL, and the NAND strings NS13, NS23, and NS33 may be arranged between a third bit line BL3 and the common source line CSL.

The string select transistors SST may be respectively connected to string select lines SSL1 to SSL3 corresponding thereto. The memory cells MCs may be respectively connected to the word lines WL1 to WL8 corresponding thereto. The ground select transistors GST may be respectively connected to ground select lines GSL1 to GSL3 corresponding thereto. The string select transistors SST may be respectively connected to the bit lines BL1 to BL3 corresponding thereto, and the ground select transistors GST may be connected to the common source line CSL. Here, the number of NAND strings, the number of word lines, the number of bit lines, the number of ground select lines, and the number of string select lines may vary depending on embodiments.

FIG. 3A is a perspective view illustrating a memory block BLKa according to an embodiment.

Referring to FIG. 3A, the memory block BLKa may correspond to one of the plurality of memory blocks BLK of FIG. 1. The memory block BLKa is formed in a vertical direction VD with respect to a substrate SUB. The substrate SUB is of a first conductivity type (e.g., a p-type), and the common source line CSL extends in a second horizontal direction HD2 over the substrate SUB. In some embodiments, the common source line CSL may be provided to the substrate SUB by doping the substrate SUB with impurities of a second conductivity type (e.g., an n-type). In some embodiments, the common source line CSL may be implemented by a conductive layer, such as a metal layer. A plurality of insulating layers IL, which extend in the second horizontal direction HD2, are provided sequentially in the vertical direction VD on the substrate SUB, and the plurality of insulating layers IL are apart from each other by as much as a certain distance in the vertical direction VD. For example, the plurality of insulating layers IL may include an insulating material, such as silicon oxide.

A plurality of pillars P, which are arranged sequentially in a first direction or a first horizontal direction HD1, are provided on the substrate SUB to penetrate the plurality of insulating layers IL in the vertical direction VD. For example, the plurality of pillars P may contact the substrate SUB through the plurality of insulating layers IL. For example, a surface layer S of each pillar P may include a silicon material of the first conductivity type and may function as a channel region. Accordingly, in some embodiments, the pillar P may be referred to as a channel structure or a vertical channel structure. An inner layer I of each pillar P may include an insulating material, such as silicon oxide, or include an air gap.

In the region of the substrate SUB between the two adjacent common source lines CSL, a charge storage layer CS is provided along exposed surfaces of the insulating layers IL, the pillars P, and the substrate SUB. The charge storage layer CS may include a gate insulating layer (that may be referred to as a “tunneling insulating layer”), a charge trap layer, and a blocking insulating layer. In some embodiments, the charge storage layer CS may have an oxide-nitride-oxide (ONO) structure. Alternatively or additionally, in the region of the substrate SUB between the two adjacent common source lines CSL, a gate electrode GE, such as the ground select line GSL, the string select line SSL, and the word lines WL1 to WL8, is provided on an exposed surface of the charge storage layer CS. Drain contacts (or drains) DR are respectively provided on the plurality of pillars P. For example, the drains DR may each include a silicon material doped with impurities of a second conductivity type. The bit lines BL1 to BL3 are provided on the drains DR to extend in the first horizontal direction HD1 and be arranged apart from each other by as much as a certain distance in the second horizontal direction HD2.

FIG. 3B is a perspective view illustrating a memory block BLKb according to an embodiment.

Referring to FIG. 3B, the memory block BLKb may correspond to one of the plurality of memory blocks BLK of FIG. 1. The memory block BLKb may correspond to a modified example of the memory block BLKa of FIG. 3A, and, as such, the descriptions made above with reference to FIG. 3A may also be applied to the BLKb of FIG. 3B. The memory block BLKb is formed in a vertical direction with respect to the substrate SUB. The memory block BLKb may include a first memory stack ST1 and a second memory stack ST2, which are stacked in the vertical direction VD.

FIG. 4 illustrates a memory device 40 having a B-VNAND structure, according to an embodiment.

Referring to FIG. 4, the memory device 40 may include a first semiconductor chip C1 and a second semiconductor chip C2, and the first and second semiconductor chips C1 and C2 may be connected to each other in a vertical direction. In some embodiments, the first and second semiconductor chips C1 and C2 may be connected to each other in a bonding manner, and thus, the memory device 40 may be referred to as a C2C memory device or a C2C bonding-structure memory device.

The first semiconductor chip C1 may include a first memory cell array MCA1 and a second memory cell array MCA2. For example, each of the first and second memory cell arrays MCA1 and MCA2 may include vertical-structure NAND strings, and thus, the memory device 40 may be referred to as a B-VNAND-structure memory device. For example, the first and second memory cell arrays MCA1 and MCA2 may be arranged adjacent to each other in the second direction HD2, and here, the memory device 40 may be referred to as a 2-MAT-structure memory device. In some embodiments, the memory device 40 may further include a memory cell array, which is arranged adjacent to the first memory cell array MCA1 in the first direction HD1, and a memory cell array, which is arranged adjacent to the second memory cell array MCA2 in the first direction HD1, and here, the memory device 40 may be referred to as a 4-MAT-structure memory device.

Alternatively or additionally, the first semiconductor chip C1 may further include bit line bonding regions 41a and 41b and word line bonding regions 42a, 42b, and 42c. Bit line bonding pads BLBP may be arranged in each of the bit line bonding regions 41a and 41b. The bit line bonding pads BLBP may be referred to as upper bit line bonding pads. Word line bonding pads WLBP may be arranged in each of the word line bonding regions 42a, 42b, and 42c, and here, the word line bonding pads WLBP may be referred to as upper word line bonding pads.

The second semiconductor chip C2 may include a plurality of peripheral regions PERI, and components of a peripheral circuit (e.g., PECT of FIG. 1) may be arranged in each peripheral region PERI. Alternatively or additionally, the second semiconductor chip C2 may further include bit line bonding regions 43a, 43b, 43c, and 43d and word line bonding regions 44a, 44b, and 44c. The bit line bonding pads BLBP may be arranged in each of the bit line bonding regions 43a, 43b, 43c, and 43d, and here, the bit line bonding pads BLBP may be referred to as lower bit line bonding pads and may be respectively connected to the upper bit line bonding pads corresponding thereto. The word line bonding pads WLBP may be arranged in each of the word line bonding regions 44a, 44b, and 44c, and here, the word line bonding pads WLBP may be referred to as lower word line bonding pads and may be respectively connected to the upper word line bonding pads corresponding thereto.

FIG. 5 illustrates a memory device 50 according to an embodiment.

Referring to FIG. 5, the memory device 50 may include the first semiconductor chip C1 and the second semiconductor chip C2. The first semiconductor chip C1 may correspond to the first semiconductor chip C1 of FIG. 4, the second semiconductor chip C2 may correspond to the second semiconductor chip C2 of FIG. 4, and the descriptions made above with reference to FIGS. 1 to 4 may also be applied to the memory device 50 of FIG. 5. The first semiconductor chip C1 may include the memory cell array 11, and the memory cell array 11 may be connected to the bit lines BL1 to BL8, the ground select line GSL, the string select line SSL, a dummy word line DWL, and the word lines WL1 and WL2. The first semiconductor chip C1 may further include a plurality of upper bonding pads respectively connected to the bit lines BL1 to BL8, the ground select line GSL, the string select line SSL, the dummy word line DWL, and the word lines WL1 and WL2. The numbers of bit lines and word lines connected to the memory cell array 11 may vary depending on embodiments, and thus, the number of upper bonding pads included in the first semiconductor chip C1 may also vary depending on embodiments.

The second semiconductor chip C2 may include the page buffer circuit 12, the word line driver 13_1, the ground select line/string select line driver 13_2, and the control logic circuit 14. Although not shown in FIG. 5, the second semiconductor chip C2 may further include the voltage generator 15, an input-output circuit, or the like. The second semiconductor chip C2 may include lower bonding pads respectively corresponding to the upper bonding pads. In some embodiments, the number of upper bonding pads may be equal to the number of lower bonding pads, and the upper bonding pads may have the same sizes as the lower bonding pads corresponding thereto, respectively. Alternatively or additionally, the number of upper bonding pads may be less than the number of lower bonding pads, and/or at least one upper bonding pad may be connected to at least two lower bonding pads. In some embodiments, the number of upper bonding pads may be greater than the number of lower bonding pads, and at least two upper bonding pads may be commonly connected to at least one lower bonding pad.

The memory device 50 may include a first region R1 and a second region R2, low-voltage bonding pad sets BPS_LV may be arranged in the first region R1, and the low-voltage bonding pad sets BPS_LV, high-voltage bonding pad sets BPS_HV, and dummy bonding pad sets BPS_DM may be arranged in the second region R2. Each of the low-voltage bonding pad sets BPS_LV may include a low-voltage upper bonding pad UBP_LV and a low-voltage lower bonding pad LBP_LV, each of the high-voltage bonding pad sets BPS_HV may include a high-voltage upper bonding pad UBP_HV1 and a high-voltage lower bonding pad LBP_HV1, and each of the dummy bonding pad sets BPS_DM may include an upper dummy bonding pad UBP_DM and a lower dummy bonding pad LBP_DM.

In the first region R1, the low-voltage bonding pad sets BPS_LV, which are respectively connected to the bit lines BL1 to BL8, may be arranged. Each low-voltage bonding pad set BPS_LV may include the low-voltage upper bonding pad UBP_LV, which is connected to one of the bit lines BL1 to BL8, and the low-voltage lower bonding pad LBP_LV, which is connected to the low-voltage upper bonding pad UBP_LV. In some embodiments, the first semiconductor chip C1 may include, in the first region R1, the low-voltage upper bonding pads UBP_LV respectively connected to the bit lines BL1 to BL8. The second semiconductor chip C2 may include, in the first region R1, the low-voltage lower bonding pads LBP_LV respectively connected to the low-voltage upper bonding pads UBP_LV.

The second region R2 may include the low-voltage bonding pad sets BPS_LV that are respectively connected to the ground select line GSL and the string select line SSL. The high-voltage bonding pad sets BPS_HV are respectively connected to the dummy word line DWL and the word lines WL1 and WL2, and the dummy bonding pad sets BPS_DM. For example, each of the dummy bonding pad sets BPS_DM may be arranged adjacent to the high-voltage bonding pad set BPS_HV. The first semiconductor chip C1 may include, in the second region R2, the high-voltage upper bonding pads UBP_HV1, which are respectively connected to the dummy word line DWL and the word lines WL1 and WL2, and the low-voltage upper bonding pads UBP_LV, which are respectively connected to the ground select line GSL and the string select line SSL. Alternatively or additionally, the first semiconductor chip C1 may further include, in the second region R2, the upper dummy bonding pads UBP_DM respectively adjacent to the high-voltage upper bonding pads UBP_HV1. The second semiconductor chip C2 may include, in the second region R2, the high-voltage lower bonding pads LBP_HV1, which are respectively connected to the high-voltage upper bonding pads UBP_HV1, the low-voltage lower bonding pads LBP_LV, which are respectively connected to the low-voltage upper bonding pads UBP_LV, and the lower dummy bonding pads LBP_DM, which are respectively connected to the upper dummy bonding pads UBP_DM.

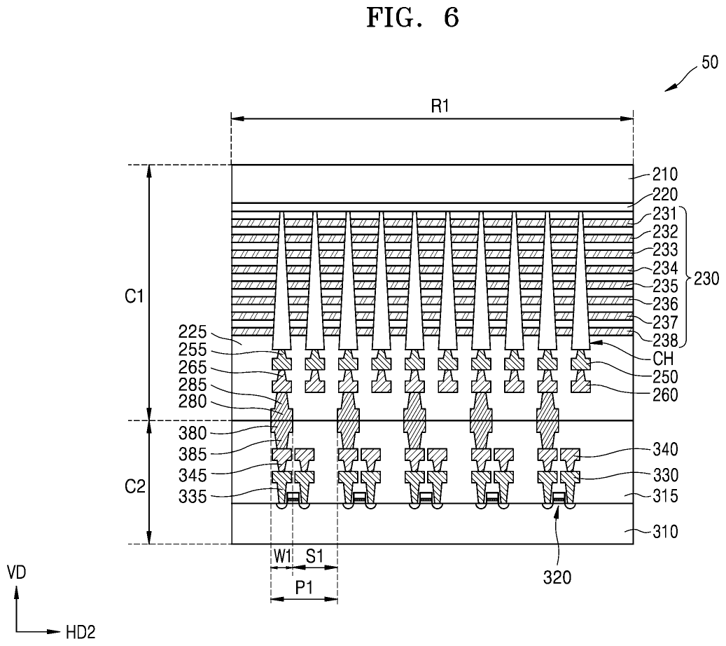

FIG. 6 is a cross-sectional view illustrating an example of the first region R1 of the memory device 50 of FIG. 5, according to an embodiment.

Referring together to FIGS. 5 and 6, the second semiconductor chip C2 of the memory device 50 may include a first substrate 310, an interlayer dielectric 315, a plurality of circuit elements 320 in the first substrate 310, a first metal layer 330 connected to each of the plurality of circuit elements 320, and a second metal layer 340 on the first metal layer 330. In some embodiments, the first metal layer 330 may be formed of tungsten having a relatively high resistance, and the second metal layer 340 may be formed of copper having a relatively low resistance. The first metal layer 330 may be connected to each of the plurality of circuit elements 320 through a first metal contact 335, and the second metal layer 340 may be connected to the first metal layer 330 through a second metal contact 345.

Although only the first metal layer 330 and the second metal layer 340 are shown in the specification, the present disclosure is not limited thereto, and one or more metal layers may be further formed on the second metal layer 340. At least some of the one or more metal layers formed on the second metal layer 340 may be formed of aluminum or the like, which has lower resistance than copper forming the second metal layer 340. The interlayer dielectric 315 may be arranged on the first substrate 310 to cover the plurality of circuit elements 320, the first metal layer 330, and the second metal layer 340 and may include an insulating material, such as silicon oxide, silicon nitride, or the like.

Lower bonding metals or lower bonding pads 380 and 385 may be formed on the second metal layer 340 in the first region R1. In the first region R1, the lower bonding pads 380 and 385 of the second semiconductor chip C2 may be electrically connected to upper bonding metals or upper bonding pads 280 and 285 of the first semiconductor chip C1 in a bonding manner, and the lower bonding pads 380 and 385 and the upper bonding pads 280 and 285 may be formed of aluminum, copper, tungsten, or the like.

The first semiconductor chip C1 may provide at least one memory block. The first semiconductor chip C1 may include a second substrate 210, a common source line 220, and an interlayer dielectric 225. A plurality of gate electrodes 231 to 238 (collectively, 230) may be stacked over the second substrate 210, in the vertical direction VD with respect to an upper surface of the second substrate 210. The plurality of gate electrodes 230 may include the word lines WL, the string select lines SSL, and the ground select line GSL. Alternatively or additionally, the plurality of gate electrodes 230 may further include at least one dummy word line DWL.

In the first region R1, a channel structure CH may extend in the vertical direction VD with respect to the upper surface of the second substrate 210 and pass through the plurality of gate electrodes 230. The channel structure CH may include a data storage layer, a channel layer, a buried insulating layer, and the like. The channel layer may be electrically connected to a first metal layer 250 and a second metal layer 260. The first metal layer 250 may be connected to the channel layer through a first metal contact 255. The second metal layer 260 may be connected to the first metal layer 250 through a second metal contact 265. For example, the first metal layer 250 may include a bit line contact, and the second metal layer 260 may include the bit lines BL1 to BL8. In some embodiments, the second metal layer 260 (e.g., the bit lines BL1 to BL8) may extend in the second direction HD2 that is parallel to the upper surface of the second substrate 210.

In some embodiments, a region, in which the channel structure CH and the second metal layer 260 (e.g., the bit lines BL1 to BL8) and the like are arranged, may be defined as the first region R1 or a bit line bonding region (e.g., 41a, 41b, and 43a to 43d in FIG. 4). The second metal layer 260 (e.g., the bit lines BL1 to BL8) may be electrically connected to the circuit elements 320 providing a page buffer circuit (e.g., 12 of FIG. 5) of the second semiconductor chip C2 in the first region R1. For example, the second metal layer 260 (e.g., the bit lines BL1 to BL8) may be respectively connected to the upper bonding pads 280 and 285 of the first semiconductor chip C1, and the upper bonding pads 280 and 285 may be respectively connected to the lower bonding pads 380 and 385 that are connected to the circuit elements 320 of the page buffer circuit. Accordingly, the page buffer circuit may be connected to the second metal layer 260 (e.g., the bit lines BL1 to BL8) through the upper and lower bonding pads 280, 285, 380, and 385.

The upper bonding pad 280 may correspond to the low-voltage upper bonding pad UBP_LV of FIG. 5 and may have a first width W1 in the second direction HD2. Alternatively or additionally, the upper bonding pad 280 may be apart from the upper bonding pad 280 adjacent thereto by as much as a first interval S1 in the second direction HD2. Accordingly, the upper bonding pad 280 may have a first pitch P1 corresponding to a sum of the first width W1 and the first interval S1. The lower bonding pad 380 may correspond to the low-voltage lower bonding pad LBP_LV of FIG. 5 and may have the first width W1 in the second direction HD2. Alternatively or additionally, the lower bonding pad 380 may be apart from the lower bonding pad 380 adjacent thereto by as much as the first interval S1 in the second direction HD2. Accordingly, the lower bonding pad 380 may have the first pitch P1 corresponding to the sum of the first width W1 and the first interval S1.

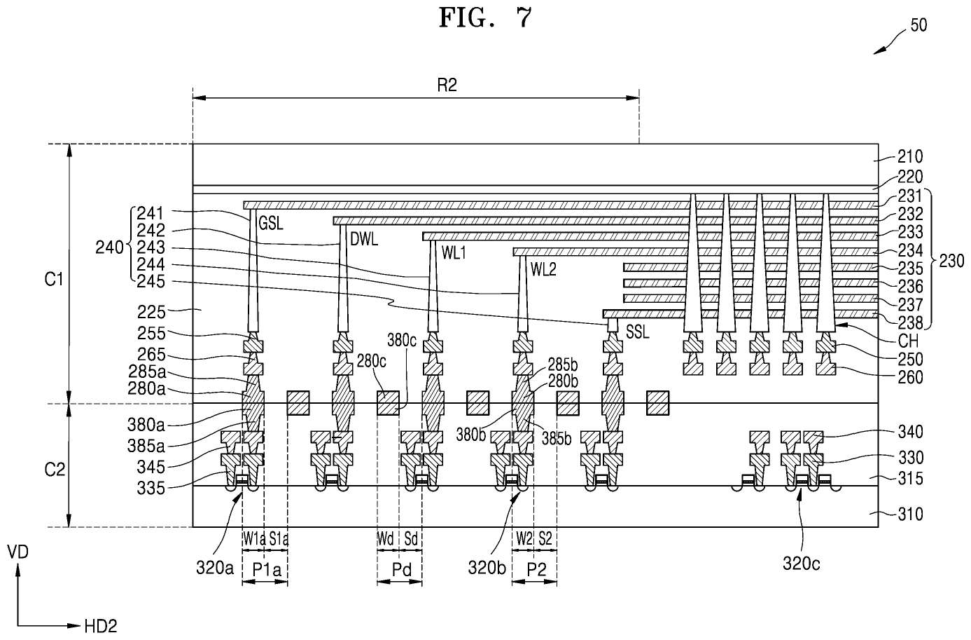

FIG. 7 is a cross-sectional view illustrating an example of the second region R2 of the memory device 50 of FIG. 5, according to an embodiment.

Referring to FIGS. 5 to 7, the first semiconductor chip C1 of the memory device 50 may further include a plurality of cell contact plugs 240 (e.g., 241 to 245), which pass through the interlayer dielectric 225 in the vertical direction VD, upper bonding pads 280a, 285a, 280b, and 285b, and upper dummy bonding pads 280c. For example, each of the upper dummy bonding pads 280c may be arranged between the upper bonding pads 280a and 280b or between the upper bonding pads 280b. Alternatively or additionally, the second semiconductor chip C2 of the memory device 50 may further include lower bonding pads 380a, 385a, 380b, and 385b, and lower dummy bonding pads 380c. For example, each of the lower dummy bonding pads 380c may be arranged between the lower bonding pads 380a and 380b or between the lower bonding pads 380b.

In some embodiments, a region, in which the plurality of cell contact plugs 240 are arranged, may be defined as the second region R2 or a word line bonding region (e.g., 42a to 42c and 44a to 44c in FIG. 4). In the second region R2, the gate electrodes 230 may extend in the second direction HD2, which is parallel to the upper surface of the second substrate 210, and may be respectively connected to the plurality of cell contact plugs 240. The first metal layer 250 and the second metal layer 260 may be arranged on and connected to, in the stated order, each of the cell contact plugs 240 that are respectively connected to the gate electrodes 230.

For example, the gate electrode 231 may correspond to the ground select line GSL, the gate electrode 232 may correspond to the dummy word line DWL, the gate electrodes 233 and 234 may respectively correspond to the word lines WL1 and WL2, and the gate electrode 235 may correspond to the string select line SSL. The cell contact plugs 241 and 245 may be respectively connected to the circuit elements 320a, which are included in the second semiconductor chip C2, through the upper bonding metals or upper bonding pads 280a and 285a of the first semiconductor chip C1 and the lower bonding metals or lower bonding pads 380a and 385a of the second semiconductor chip C2, in the second region R2. For example, the circuit elements 320a may be included in the ground select line/string select line driver 13_2. The cell contact plugs 242, 243, and 244 may be respectively connected to the circuit elements 320b, which are included in the second semiconductor chip C2, through the upper bonding pads 280b and 285b of the first semiconductor chip C1 and the lower bonding pads 380b and 385b of the second semiconductor chip C2, in the second region R2. For example, the circuit elements 320b may be included in the word line driver 13_1. Alternatively or additionally, the second semiconductor chip C2 may further include circuit elements 320c overlapping the plurality of channel structures CH in the vertical direction VD.

As such, the cell contact plugs 240 may be electrically connected to the circuit elements 320a and 320b, which provide a row decoder or the word line driver 13_1 and the ground select line/string select line driver 13_2, in the second semiconductor chip C2. In some embodiments, operating voltages of the circuit elements 320a and 320b, which provide the row decoder or the word line driver 13_1 and the ground select line/string select line driver 13_2, may be different from operating voltages of the circuit elements 320, which provide the page buffer circuit 12. For example, the operating voltages of the circuit elements 320b providing the word line driver 13_1 may be greater than the operating voltages of the circuit elements 320 providing the page buffer circuit 12.

The upper bonding pad 280a may correspond to the low-voltage upper bonding pad UBP_LV of FIG. 5 and may have a first width W1a in the second direction HD2. Alternatively or additionally, the upper bonding pad 280a may be apart from the upper bonding pad 280a adjacent thereto by as much as a first interval S1a in the second direction HD2. Accordingly, the upper bonding pad 280a may have a first pitch P1a corresponding to a sum of the first width W1a and the first interval S1a. The lower bonding pad 380a may correspond to the low-voltage lower bonding pad LBP_LV of FIG. 5 and may have the first width W1a in the second direction HD2. Alternatively or additionally, the lower bonding pad 380a may be apart from the lower bonding pad 380a adjacent thereto by as much as the first interval S1a in the second direction HD2. Accordingly, the lower bonding pad 380a may have the first pitch P1a corresponding to the sum of the first width W1a and the first interval S1a. For example, the first width W1a may be equal to the first width W1 of FIG. 6, but the present disclosure is not limited thereto. For example, the first interval S1a may be equal to the first interval S1 of FIG. 6, but the present disclosure is not limited thereto. For example, the first pitch P1a may be equal to the first pitch P1 of FIG. 6, but the present disclosure is not limited thereto.

The upper bonding pad 280b may correspond to the high-voltage upper bonding pad UBP_HV1 of FIG. 5 and may have a second width W2 in the second direction HD2. Alternatively or additionally, the upper bonding pad 280b may be apart from the upper dummy bonding pad 280c adjacent thereto by as much as a second interval S2 in the second direction HD2. Accordingly, the upper bonding pad 280b may have a second pitch P2 corresponding to a sum of the second width W2 and the second interval S2. The lower bonding pad 380b may correspond to the high-voltage lower bonding pad LBP_HV1 of FIG. 5 and may have the second width W2 in the second direction HD2. Alternatively or additionally, the lower bonding pad 380b may be apart from the lower dummy bonding pad 380c adjacent thereto by as much as the second interval S2 in the second direction HD2. Accordingly, the lower bonding pad 380b may have the second pitch P2 corresponding to the sum of the second width W2 and the second interval S2. For example, the second width W2 may be greater than or equal to the first width W1a, but the present disclosure is not limited thereto. For example, the second interval S2 may be greater than or equal to the first interval Sla, but the present disclosure is not limited thereto. For example, the second pitch P2 may be greater than or equal to the first pitch P1a, but the present disclosure is not limited thereto.

The upper dummy bonding pad 280c may correspond to the upper dummy bonding pad UBP_DM of FIG. 5 and may have a third width Wd in the second direction HD2. Alternatively or additionally, the upper dummy bonding pad 280c may be apart from the upper bonding pad 280b adjacent thereto by as much as a third interval Sd in the second direction HD2. Accordingly, the upper dummy bonding pad 280c may have a third pitch Pd corresponding to a sum of the third width Wd and the third interval Sd. The lower dummy bonding pad 380c may correspond to the lower dummy bonding pad LBP_DM of FIG. 5 and may have the third width Wd in the second direction HD2. Alternatively or additionally, the lower dummy bonding pad 380c may be apart from the lower bonding pad 380b adjacent thereto by as much as the third interval Sd in the second direction HD2. Accordingly, the lower dummy bonding pad 380c may have the third pitch Pd corresponding to the sum of the third width Wd and the third interval Sd.

For example, the third width Wd may be greater than the first width W1a, but the present disclosure is not limited thereto. For example, the third interval Sd may be greater than the first interval S1a, but the present disclosure is not limited thereto. For example, the third pitch Pd may be greater than the first pitch P1a, but the present disclosure is not limited thereto. For example, the third width Wd may be equal to the first width W1a or the second width W2, but the present disclosure is not limited thereto. For example, the third interval Sd may be equal to the first interval S1a or the second interval S2, but the present disclosure is not limited thereto. For example, the third pitch Pd may be equal to the first pitch P1a or the second pitch P2, but the present disclosure is not limited thereto.

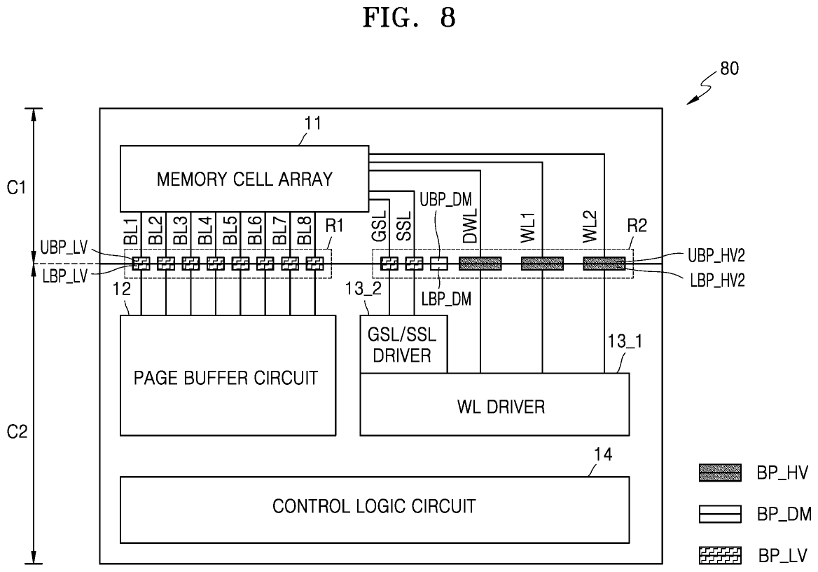

FIG. 8 illustrates a memory device 80 according to an embodiment.

Referring to FIG. 8, the memory device 80 may correspond to a modified example of the memory device 50 of FIG. 5. Hereinafter, repeated descriptions are omitted, and differences between the memory device 50 of FIG. 5 and the memory device 80 are mainly described. In some embodiments, the second region R2 may include the low-voltage bonding pad sets BPS_LV, which are respectively connected to the ground select line GSL and the string select line SSL, the high-voltage bonding pad sets BPS_HV, which are respectively connected to the dummy word line DWL and the word lines WL1 and WL2, and the dummy bonding pad sets BPS_DM. For example, each of the dummy bonding pad sets BPS_DM may be arranged adjacent to the high-voltage bonding pad set BPS_HV.

In some embodiments, the first semiconductor chip C1 may include, in the second region R2, high-voltage upper bonding pads UBP_HV2, which are respectively connected to the dummy word line DWL and the word lines WL1 and WL2, and the low-voltage upper bonding pads UBP_LV, which are respectively connected to the ground select line GSL and the string select line SSL. Alternatively or additionally, the first semiconductor chip C1 may further include, in the second region R2, the upper dummy bonding pad UBP_DM that is adjacent to the high-voltage upper bonding pad UBP_HV2. In some embodiments, the second semiconductor chip C2 may include, in the second region R2, high-voltage lower bonding pads LBP_HV2, which are respectively connected to the high-voltage upper bonding pads UBP_HV2, the low-voltage lower bonding pads LBP_LV, which are respectively connected to the low-voltage upper bonding pads UBP_LV, and the lower dummy bonding pads LBP_DM each connected to the upper dummy bonding pad UBP_DM.

In some embodiments, the size of each of the high-voltage upper bonding pads UBP_HV2 may be greater than the size of each of the high-voltage upper bonding pads UBP_HV1 of FIG. 5. In some embodiments, the pitch of each of the high-voltage upper bonding pads UBP_HV2 may be greater than the pitch of each of the high-voltage upper bonding pads UBP_HV1 of FIG. 5. In some embodiments, the upper dummy bonding pad UBP_DM may not be arranged between the high-voltage upper bonding pads UBP_HV2 adjacent to each other. In some embodiments, the size of each of the high-voltage lower bonding pads LBP_HV2 may be greater than the size of each of the high-voltage lower bonding pads LBP_HV1 of FIG. 5. In some embodiments, the pitch of each of the high-voltage lower bonding pads LBP_HV2 may be greater than the pitch of each of the high-voltage lower bonding pads LBP_HV1 of FIG. 5. In some embodiments, the lower dummy bonding pad LBP_DM may not be arranged between the high-voltage lower bonding pads LBP_HV2 adjacent to each other.

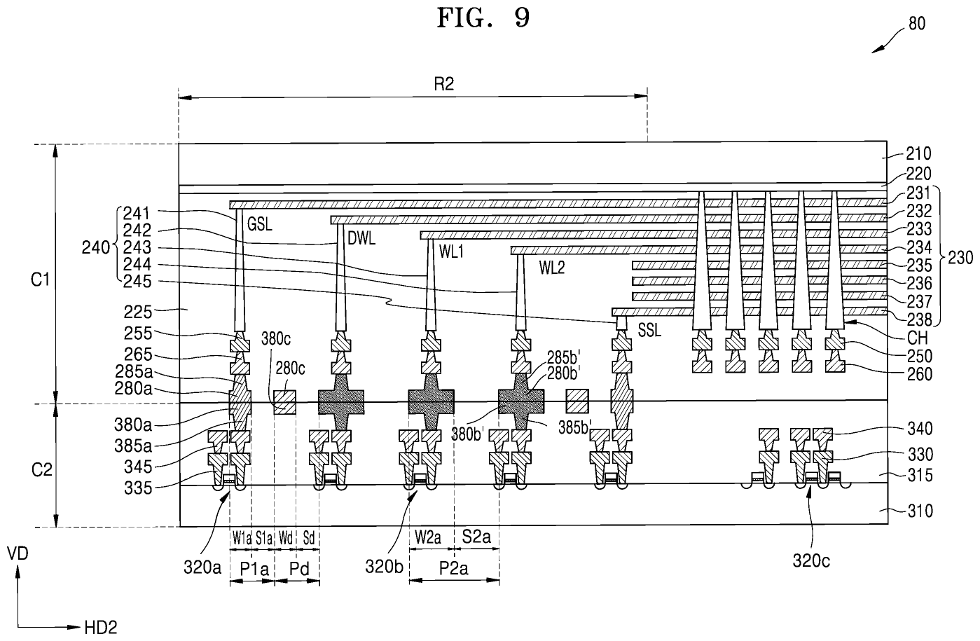

FIG. 9 is a cross-sectional view illustrating an example of the second region R2 of the memory device 80 of FIG. 8, according to an embodiment. The memory device 80 shown in FIG. 9 corresponds to a modified example of the memory device 50 of FIG. 7, and repeated descriptions thereof are omitted.

Referring together to FIGS. 8 and 9, the first semiconductor chip C1 of the memory device 80 may include upper bonding pads 280a, 285a, 280b′, and 285b′ and the upper dummy bonding pad 280c. For example, the upper dummy bonding pad 280c may be arranged between the upper bonding pads 280a and 280b′. Alternatively or additionally, the second semiconductor chip C2 of the memory device 80 may include lower bonding pads 380a, 385a, 380b′, and 385b′ and the lower dummy bonding pad 380c. For example, the lower dummy bonding pad 380c may be arranged between the lower bonding pads 380a and 380b′.

The upper bonding pad 280b′ may correspond to the high-voltage upper bonding pad UBP_HV1 of FIG. 5 and may have a second width W2a in the second direction HD2. Alternatively or additionally, the upper bonding pad 280b′ may be apart from the upper bonding pad 280b′ adjacent thereto by as much as a second interval S2a in the second direction HD2. Accordingly, the upper bonding pad 280b′ may have a second pitch P2a corresponding to a sum of the second width W2a and the second interval S2a. The lower bonding pad 380b′ may correspond to the high-voltage lower bonding pad LBP_HV1 of FIG. 5 and may have the second width W2a in the second direction HD2. Alternatively or additionally, the lower bonding pad 380b′ may be apart from the lower bonding pad 380b′ adjacent thereto by as much as the second interval S2a in the second direction HD2. Accordingly, the lower bonding pad 380b′ may have the second pitch P2a corresponding to the sum of the second width W2a and the second interval S2a. For example, the second width W2a may be greater than the second width W2 of FIG. 7. For example, the second interval S2a may be greater than the second interval S2 of FIG. 7. For example, the second pitch P2a may be greater than the second pitch P2 of FIG. 7.

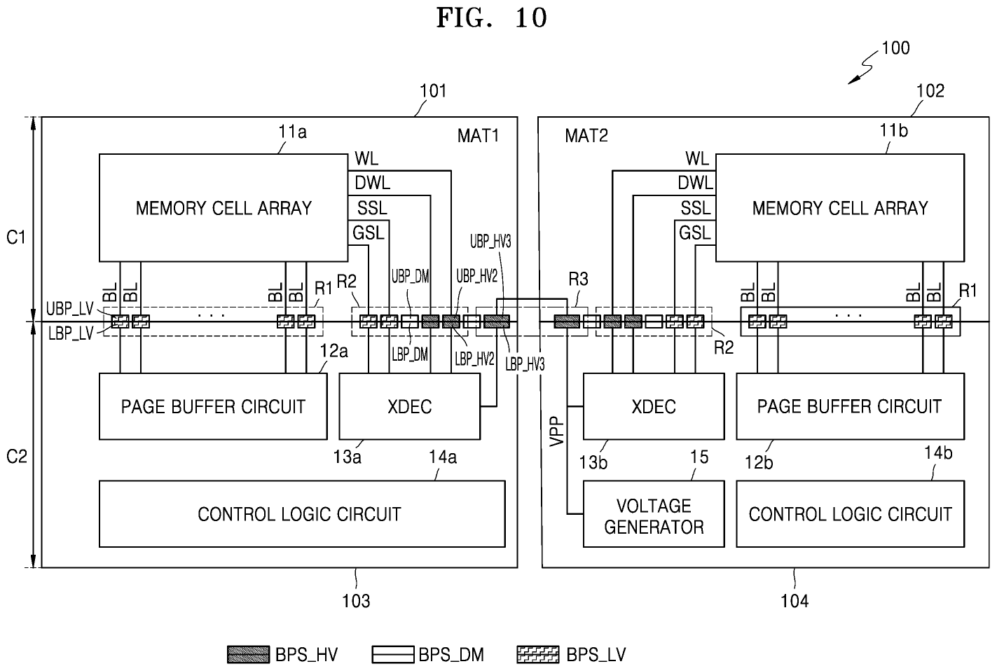

FIG. 10 illustrates a memory device 100 according to an embodiment.

Referring to FIG. 10, the memory device 100 may include the first semiconductor chip C1 and the second semiconductor chip C2, the first semiconductor chip C1 may include a first cell region 101 and a second cell region 102, and the second semiconductor chip C2 may include a first peripheral region 103 and a second peripheral region 104. The first and second cell regions 101 and 102 may be arranged adjacent to each other in the first direction or the second direction in the first semiconductor chip C1, and the first and second peripheral regions 103 and 104 may be arranged adjacent to each other in the first direction or the second direction in the second semiconductor chip C2.

The first cell region 101 may include a first memory cell array 11a and a plurality of upper bonding pads, and the first cell region 101 or the first memory cell array 11a may be referred to as a first MAT (e.g., MAT1). The second cell region 102 may include a second memory cell array 11b and a plurality of upper bonding pads, and the second cell region 102 or the second memory cell array 11b may be referred to as a second MAT (e.g., MAT2). Each of the first and second memory cell arrays 11a and 11b may include a plurality of memory blocks, and each of the plurality of memory blocks may include a plurality of NAND strings extending in a vertical direction.

The first peripheral region 103 may correspond to the first cell region 101 and may be connected to the first cell region 101 in the vertical direction in a bonding manner, for example, a C2C bonding manner. The first peripheral region 103 may include a page buffer circuit 12a, a row decoder 13a, a control logic circuit 14a, and a plurality of lower bonding pads. The second peripheral region 104 may correspond to the second cell region 102 and may be connected to the second cell region 102 in the vertical direction in a bonding manner, for example, a C2C bonding manner. The second peripheral region 104 may include a page buffer circuit 12b, a row decoder 13b, a control logic circuit 14b, the voltage generator 15, and a plurality of lower bonding pads. Although not shown in FIG. 10, the first peripheral region 103 may also include the voltage generator 15, and each of the first and second peripheral regions 103 and 104 may further include various circuits, such as an input-output circuit and the like.

The memory device 100 may include first to third regions R1, R2, and R3. In some embodiments, the first region R1 may be defined as a region in which the low-voltage bonding pad sets BPS_LV are arranged, the second region R2 may be defined as a region in which the low-voltage bonding pad sets BPS_LV, the high-voltage bonding pad sets BPS_HV, and the dummy bonding pad sets BPS_DM are arranged, and the third region R3 may be defined as a region in which the high-voltage bonding pad sets BPS_HV and the dummy bonding pad sets BPS_DM are arranged.

For example, the regions corresponding to the page buffer circuits 12a and 12b may be defined as first region R1, respectively. Accordingly, a plurality of bonding pad sets for making wiring connection between the bit lines BL and each of the page buffer circuits 12a and 12b may be arranged in the first region R1. The first cell region 101 may include, in the first region R1, the low-voltage upper bonding pads UBP_LV respectively connected to the bit lines BL, and the first peripheral region 103 may include, in the first region R1, the low-voltage lower bonding pads LBP_LV respectively connected to the low-voltage upper bonding pads UBP_LV. Likewise, the second cell region 102 may include, in the first region R1, the low-voltage upper bonding pads UBP_LV respectively connected to the bit lines BL, and the second peripheral region 104 may include, in the first region R1, the low-voltage lower bonding pads LBP_LV respectively connected to the low-voltage upper bonding pads UBP_LV.

For example, the regions corresponding to the row decoders 13a and 13b may be defined as second region R2, respectively. Accordingly, a plurality of bonding pad sets for making wiring connection between each of the row decoders 13a and 13b and all of the ground select line GSL, the string select line SSL, the dummy word line DWL, and the word line WL may be arranged in the second region R2. The first cell region 101 may include, in the second region R2, the low-voltage upper bonding pads UBP_LV, which are respectively connected to the ground select line GSL and the string select line SSL, the high-voltage upper bonding pads UBP_HV2, which are respectively connected to the dummy word line DWL and the word line WL, and the upper dummy bonding pad UBP_DM. Alternatively or additionally, the first peripheral region 103 may include, in the second region R2, the low-voltage lower bonding pads LBP_LV, which are respectively connected to the low-voltage upper bonding pads UBP_LV, the high-voltage lower bonding pads LBP_HV2, which are respectively connected to the high-voltage upper bonding pads UBP_HV2, and the lower dummy bonding pad LBP_DM connected to the upper dummy bonding pad UBP_DM. Likewise, the second cell region 102 may include, in the second region R2, the low-voltage upper bonding pads UBP_LV, which are respectively connected to the ground select line GSL and the string select line SSL, the high-voltage upper bonding pads UBP_HV2, which are respectively connected to the dummy word line DWL and the word line WL, and the upper dummy bonding pad UBP_DM, and the second peripheral region 104 may include, in the second region R2, the low-voltage lower bonding pads LBP_LV, which are respectively connected to the low-voltage upper bonding pads UBP_LV, the high-voltage lower bonding pads LBP_HV2, which are respectively connected to the high-voltage upper bonding pads UBP_HV2, and the lower dummy bonding pad LBP_DM connected to the upper dummy bonding pad UBP_DM.

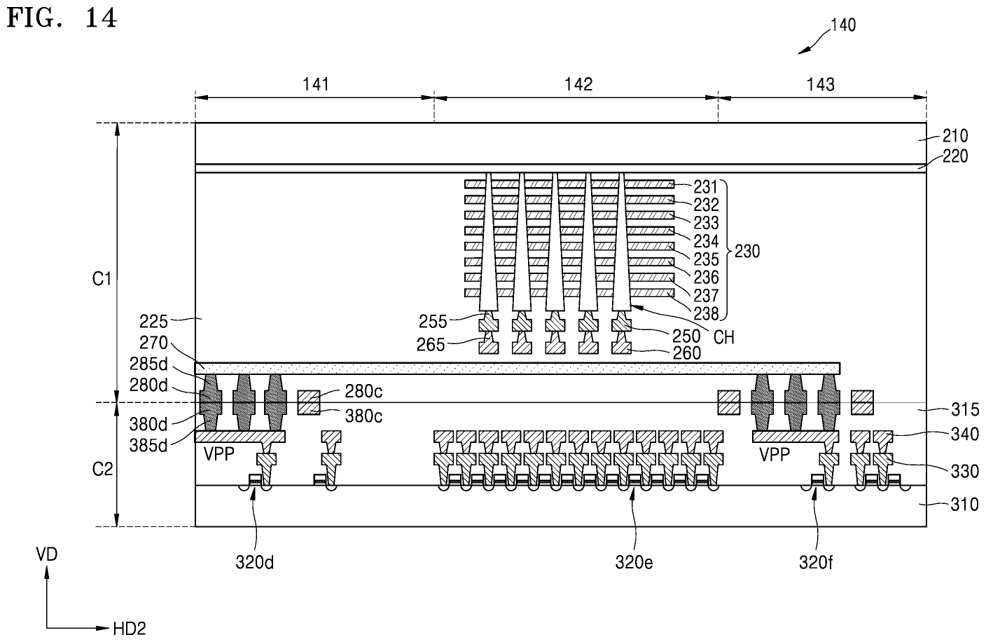

For example, a region connecting the first peripheral region 103 to the second peripheral region 104 may be defined as the third region R3. Accordingly, a plurality of bonding pad sets for making wiring connection between the row decoder 13a of the first peripheral region 103 and the voltage generator 15 and the row decoder 13b of the second peripheral region 104 may be arranged in the third region R3. The first peripheral region 103 may include, in the third region R3, a high-voltage lower bonding pad LBP_HV3 connected to the row decoder 13a, and the first cell region 101 may include, in the third region R3, a high-voltage upper bonding pad UBP_HV3 connected to the high-voltage lower bonding pad LBP_HV3. Alternatively or additionally, the second peripheral region 104 may include, in the third region R3, the high-voltage lower bonding pad LBP_HV3 connected to the voltage generator 15 and the row decoder 13b. In some embodiments, the second cell region 102 may include, in the third region R3, the high-voltage upper bonding pad UBP_HV3 connected to the high-voltage lower bonding pad LBP_HV3. Here, the first semiconductor chip C1 may further include a metal layer for electrically connecting the high-voltage lower bonding pads LBP_HV3 to each other. This will be described below in detail with reference to FIGS. 14 to 17.

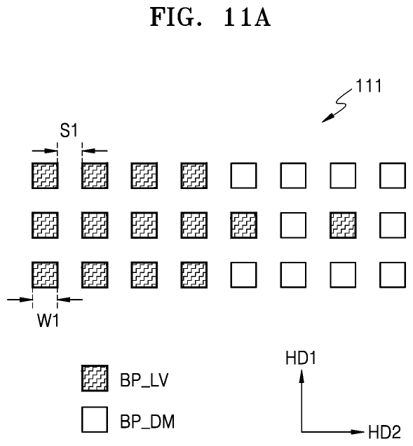

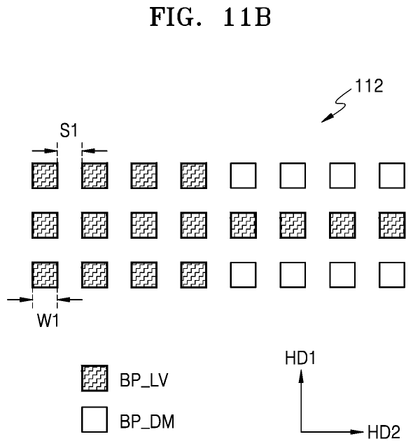

FIGS. 11A and 11B are plan views respectively illustrating examples of bonding pads arranged in the first region R1 of the memory device 100 of FIG. 10, according to some embodiments.

Referring to FIG. 11A, a memory device 111 may include a plurality of low-voltage bonding pads BP_LV and a plurality of dummy bonding pads BP_DM, which are adjacent to each other in the first direction HD1 and the second direction HD2. For example, the plurality of low-voltage bonding pads BP_LV and the plurality of dummy bonding pads BP_DM may be arranged on one surface of the first semiconductor chip C1. For example, the plurality of low-voltage bonding pads BP_LV and the plurality of dummy bonding pads BP_DM may be arranged on one surface of the second semiconductor chip C2. Each low-voltage bonding pad BP_LV may have the first width W1 in the second direction HD2, and the low-voltage bonding pads BP_LV adjacent to each other may be apart from each other by as much as the first interval S1. Here, the first direction HD1 and the second direction HD2 may vary depending on embodiments.

For example, each of the first and third rows may include four low-voltage bonding pads BP_LV adjacent to each other in the second direction HD2 and four dummy bonding pads BP_DM adjacent to each other in the second direction HD2. For example, the second row may include five low-voltage bonding pads BP_LV arranged in the second direction HD2 and may further include the dummy bonding pads BP_DM arranged between the low-voltage bonding pads BP_LV adjacent to each other.

Referring to FIG. 11B, a memory device 112 corresponds to a modified example of the memory device 111 of FIG. 11A, and repeated descriptions thereof are omitted. For example, each of the first and third rows may include four low-voltage bonding pads BP_LV adjacent to each other in the second direction HD2 and four dummy bonding pads BP_DM adjacent to each other in the second direction HD2. For example, the second row may include eight low-voltage bonding pads BP_LV arranged in the second direction HD2.

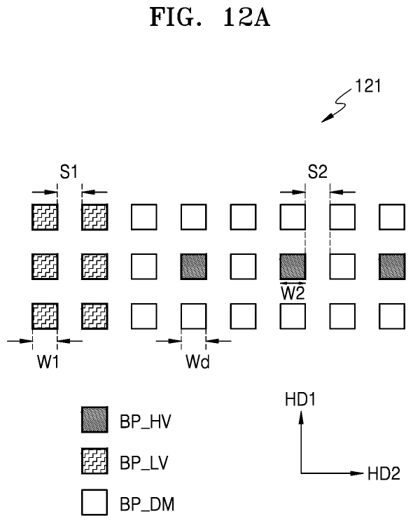

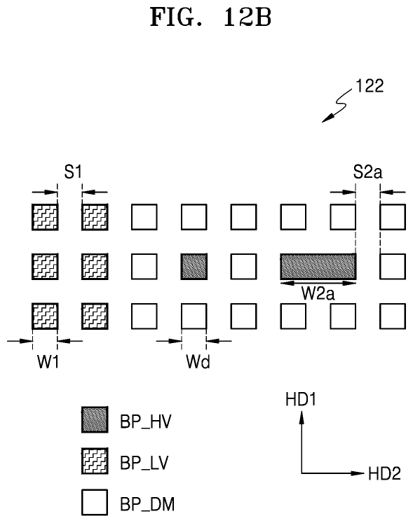

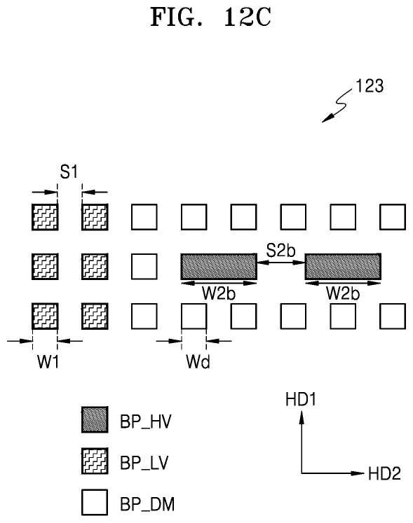

FIGS. 12A to 12C are plan views respectively illustrating examples of bonding pads arranged in the second region R2 of the memory device 100 of FIG. 10, according to some embodiments. The descriptions made above with reference to FIGS. 11A and 11B may also be applied to the memory devices illustrated in FIGS. 12A to 12C.

Referring to FIG. 12A, a memory device 121 may include the plurality of low-voltage bonding pads BP_LV, a plurality of high-voltage bonding pads BP_HV, and the plurality of dummy bonding pads BP_DM, which are adjacent to each other in the first direction HD1 and the second direction HD2. For example, the plurality of low-voltage bonding pads BP_LV, the plurality of high-voltage bonding pads BP_HV, and the plurality of dummy bonding pads BP_DM may be arranged on one surface of the first semiconductor chip C1. As another example, the plurality of low-voltage bonding pads BP_LV, the plurality of high-voltage bonding pads BP_HV, and the plurality of dummy bonding pads BP_DM may be arranged on one surface of the second semiconductor chip C2.

Each low-voltage bonding pad BP_LV may have the first width W1 in the second direction HD2, and the low-voltage bonding pads BP_LV adjacent to each other may be apart from each other by as much as the first interval S1. Each high-voltage bonding pad BP_HV may have the second width W2 in the second direction HD2 and may be apart from the dummy bonding pad BP_DM adjacent thereto by as much as the second interval S2. Each dummy bonding pad BP_LV may have the third width Wd in the second direction HD2. Here, the first direction HD1 and the second direction HD2 may vary depending on embodiments. For example, the second width W2 or the third width Wd may be greater than or equal to the first width W1, but the present disclosure is not limited thereto. For example, the second interval S2 may be greater than or equal to the first interval S1.

Referring to FIG. 12B, a memory device 122 corresponds to a modified example of the memory device 121 of FIG. 12A, and repeated descriptions thereof are omitted. At least one of the plurality of high-voltage bonding pads BP_HV may have the second width W2a and may be apart from the dummy bonding pad BP_DM adjacent thereto by as much as the second interval S2a. For example, the second width W2a may be greater than the first width W1. For example, the second interval S2a may be greater than or equal to the first interval S1, but the present disclosure is not limited thereto.

Referring to FIG. 12C, a memory device 123 corresponds to a modified example of the memory device 121 of FIG. 12A, and repeated descriptions thereof are omitted. Each high-voltage bonding pad BP_HV may have a second width W2b and may be apart from the high-voltage bonding pad BP_HV adjacent thereto by as much as a second interval S2b. For example, the second width W2b may be greater than the first width W1. For example, the second interval S2b may be greater than or equal to the first interval S1, but the present disclosure is not limited thereto.

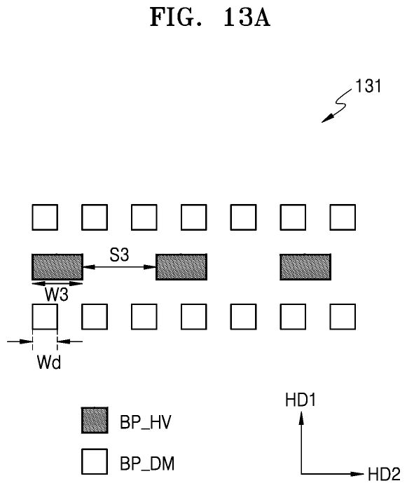

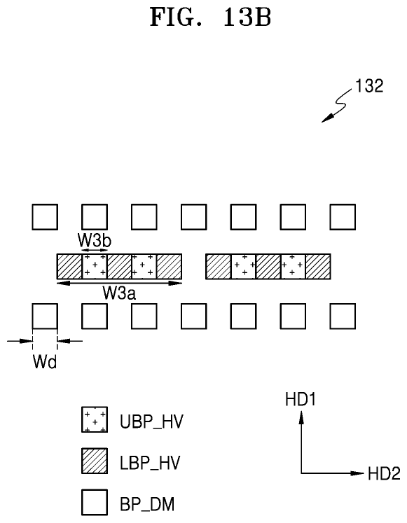

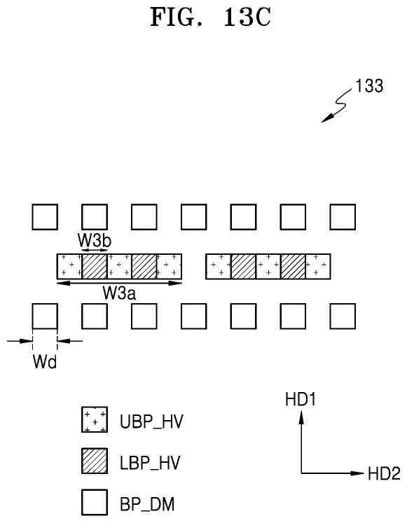

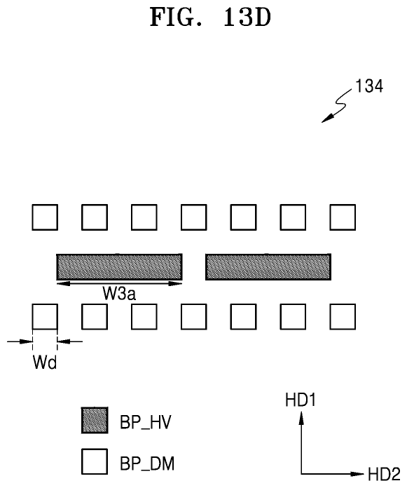

FIGS. 13A to 13D are plan views respectively illustrating examples of bonding pads arranged in the third region R3 of the memory device 100 of FIG. 10, according to some embodiments. The descriptions made above with reference to FIGS. 11A and 11B may also be applied to the memory devices illustrated in FIGS. 13A to 13C.

Referring to FIG. 13A, a memory device 131 may include the plurality of high-voltage bonding pads BP_HV adjacent to each other in the second direction HD2 and the plurality of dummy bonding pads BP_DM adjacent to each other in the second direction HD2. For example, the plurality of high-voltage bonding pads BP_HV and the plurality of dummy bonding pads BP_DM may be arranged on one surface of the first semiconductor chip C1. As another example, the plurality of high-voltage bonding pads BP_HV and the plurality of dummy bonding pads BP_DM may be arranged on one surface of the second semiconductor chip C2.

Each high-voltage bonding pad BP_HV may have a fourth width W3 in the second direction HD2 and may be apart from the high-voltage bonding pad BP_HV adjacent thereto by as much as a fourth interval S3. Each dummy bonding pad BP_LV may have the third width Wd in the second direction HD2. Here, the first direction HD1 and the second direction HD2 may vary depending on embodiments. For example, the fourth width W3 may be greater than or equal to the third width Wd, but the present disclosure is not limited thereto. In some embodiments, at least one dummy bonding pad BP_DM may be arranged between the high-voltage bonding pads BP_HV adjacent to each other.

Referring to FIG. 13B, a memory device 132 corresponds to a modified example of the memory device 131 of FIG. 13A, and repeated descriptions thereof are omitted. For example, a plurality of upper high-voltage bonding pads UBP_HV and the plurality of dummy bonding pads BP_DM may be arranged on one surface of the first semiconductor chip C1. As another example, a plurality of lower high-voltage bonding pads LBP_HV and the plurality of dummy bonding pads BP_DM may be arranged on one surface of the second semiconductor chip C2. Each lower high-voltage bonding pad LBP_HV may have a fourth width W3a in the second direction HD2, and each upper high-voltage bonding pad UBP_HV may have a fourth width W3b in the second direction HD2. Here, the fourth width W3a may be greater than the fourth width W3b. For example, two upper high-voltage bonding pads UBP_HV arranged in a line in the second direction HD2 may be commonly connected to one lower high-voltage bonding pad LBP_HV.

Referring to FIG. 13C, a memory device 133 corresponds to a modified example of the memory device 131 of FIG. 13A, and repeated descriptions thereof are omitted. For example, the plurality of upper high-voltage bonding pads UBP_HV and the plurality of dummy bonding pads BP_DM may be arranged on one surface of the first semiconductor chip C1. As another example, the plurality of lower high-voltage bonding pads LBP_HV and the plurality of dummy bonding pads BP_DM may be arranged on one surface of the second semiconductor chip C2. Each lower high-voltage bonding pad LBP_HV may have the fourth width W3b in the second direction HD2, and each upper high-voltage bonding pad UBP_HV may have the fourth width W3a in the second direction HD2. Here, the fourth width W3a may be greater than the fourth width W3b. For example, two lower high-voltage bonding pads LBP_HV arranged in a line in the second direction HD2 may be commonly connected to one upper high-voltage bonding pad UBP_HV.

Referring to FIG. 13D, a memory device 134 corresponds to a modified example of the memory device 131 of FIG. 13A, and repeated descriptions thereof are omitted. For example, the plurality of high-voltage bonding pads BP_HV and the plurality of dummy bonding pads BP_DM may be arranged on one surface of the first semiconductor chip C1. As another example, the plurality of high-voltage bonding pads BP_HV and the plurality of dummy bonding pads BP_DM may be arranged on one surface of the second semiconductor chip C2. Each high-voltage bonding pad BP_HV may have the fourth width W3a in the second direction HD2, and each dummy bonding pad BP_DM may have the third width Wd in the second direction HD2. Here, the fourth width W3a may be greater than the third width Wd. In some embodiments, at least one dummy bonding pad BP_DM may be arranged between the high-voltage bonding pads BP_HV adjacent to each other. For example, the fourth width W3a may be greater than the fourth width W3 of FIG. 13A.

FIG. 14 is a cross-sectional view illustrating a memory device 140 according to an embodiment.

Referring together to FIGS. 10 and 14, the memory device 140 may correspond to an example of the memory device 100 of FIG. 10, and the descriptions made above with reference to FIGS. 6, 7, 9, and 10 may also be applied to the memory device 140 of FIG. 14. The memory device 140 may include first to third regions 141 to 143. For example, the second region 142 may correspond to a certain region of the first or second memory cell array MCA1 or MCA2 of FIG. 4. As another example, the first region 141 may correspond to the third region R3 of each of the first cell region 101 and the first peripheral region 103 in FIG. 10, and the third region 143 may correspond to the third region R3 of each of the second cell region 102 and the second peripheral region 104 in FIG. 10.

The second semiconductor chip C2 may include, in the first region 141, the circuit elements 320a, the first and second metal layers 330 and 340, lower high-voltage bonding pads 380d and 385d, and the lower dummy bonding pads 380c. For example, the circuit elements 320a may be included in the row decoder 13a of the first peripheral region 103 of FIG. 10. Alternatively or additionally, the second semiconductor chip C2 may include, in the third region 143, the circuit elements 320c, the first and second metal layers 330 and 340, the lower high-voltage bonding pads 380d and 385d, and the lower dummy bonding pads 380c. For example, the circuit elements 320c may be included in the voltage generator 15 or the row decoder 13b of the second peripheral region 104 of FIG. 10. Alternatively or additionally, the second semiconductor chip C2 may include the circuit elements 320b in the second region 142. For example, the circuit elements 320b may be included in the page buffer circuit 12a or the control logic circuit 14a of the first peripheral region 103. As another example, the circuit elements 320b may be included in the page buffer circuit 12b or the control logic circuit 14b of the second peripheral region 104.

The first semiconductor chip C1 may include, in the first and third regions 141 and 143, the upper high-voltage bonding pads 280d and 285d and the upper dummy bonding pads 280c. Alternatively or additionally, the first semiconductor chip C1 may include, in the second region 142, the plurality of gate electrodes 230, the plurality of channel structures CH, the first metal layer 250, and the second metal layer 260. Furthermore, the first semiconductor chip C1 may include, in the first to third regions 141 to 143, a third metal layer 270 for connecting the upper high-voltage bonding pads 280d and 285d to each other. For example, the third metal layer 270 may extend in the second direction HD2.

In some embodiments, the upper high-voltage bonding pads 280d and the lower high-voltage bonding pads 380d may correspond to the high-voltage bonding pads BP_HV of FIG. 13A, and the upper dummy bonding pads 280c and the lower dummy bonding pads 380c may correspond to the dummy bonding pads BP_DM of FIG. 13A. In some embodiments, a high voltage VPP generated by the circuit element 320c, for example, the voltage generator 15, which is included in the third region 143, may be transferred to the circuit element 320a, for example, the row decoder 13a, which is included in the first region 141, through the first and second metal layers 330 and 340, the lower high-voltage bonding pads 380d, the upper high-voltage bonding pads 280d, and the third metal layer 270.

In some embodiments, the size or pitch of each of the lower high-voltage bonding pads 380d may be greater than the size or pitch of each of the lower dummy bonding pads 380c. In some embodiments, the size or pitch of each of the upper high-voltage bonding pads 280d may be greater than the size or pitch of each of the upper dummy bonding pads 280c. In some embodiments, the size or pitch of each of the upper high-voltage bonding pads 280d may be substantially equal to the size or pitch of each of the lower high-voltage bonding pads 380d corresponding thereto. In some embodiments, the number of upper high-voltage bonding pads 280d may be equal to the number of lower high-voltage bonding pads 380d. In some embodiments, the size or pitch of each of the upper dummy bonding pads 280c may be substantially equal to the size or pitch of each of the lower dummy bonding pads 380c corresponding thereto. In some embodiments, the number of upper dummy bonding pads 280c may be equal to the number of lower dummy bonding pads 380c.

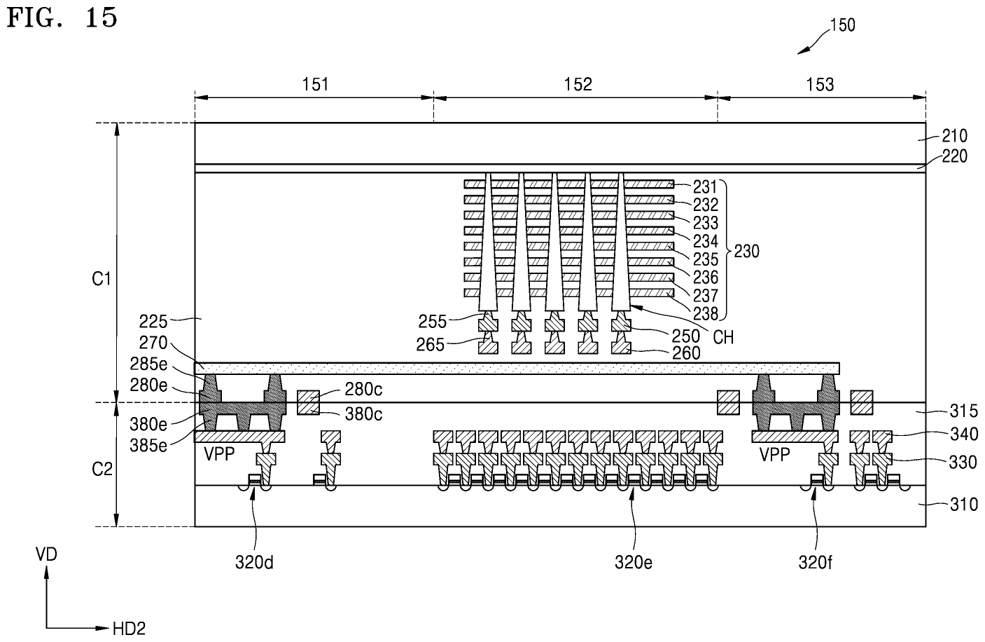

FIG. 15 is a cross-sectional view illustrating a memory device 150 according to an embodiment.

Referring together to FIGS. 10 and 15, the memory device 150 may correspond to an example of the memory device 100 of FIG. 10 and may correspond to a modified example of the memory device 140 of FIG. 14. Thus, the descriptions made above with reference to FIG. 14 may be applied to the memory device 150 of FIG. 15, and repeated descriptions thereof are omitted. The memory device 150 may include first to third regions 151, 152, and 153. For example, the second region 152 may correspond to a certain region of the first or second memory cell array MCA1 or MCA2 of FIG. 4. As another example, the first region 151 may correspond to the third region R3 of each of the first cell region 101 and the first peripheral region 103 in FIG. 10, and the third region 153 may correspond to the third region R3 of each of the second cell region 102 and the second peripheral region 104 in FIG. 10.

The second semiconductor chip C2 may include, in the first region 151, the circuit elements 320a, the first and second metal layers 330 and 340, lower high-voltage bonding pads 380e and 385e, and the lower dummy bonding pads 380c. Alternatively or additionally, the second semiconductor chip C2 may include, in the third region 153, the circuit elements 320c, the first and second metal layers 330 and 340, the lower high-voltage bonding pads 380e and 385e, and the lower dummy bonding pads 380c. The first semiconductor chip C1 may include, in the first and third regions 151 and 153, upper high-voltage bonding pads 280e and 285e and the upper dummy bonding pads 280c. Alternatively or additionally, the first semiconductor chip C1 may include, in the second region 152, the plurality of gate electrodes 230, the plurality of channel structures CH, the first metal layer 250, and the second metal layer 260. Furthermore, the first semiconductor chip C1 may include, in the first to third regions 151 to 153, the third metal layer 270 for connecting the upper high-voltage bonding pads 280e and 285e to each other.

In some embodiments, the upper high-voltage bonding pads 280e may correspond to the upper high-voltage bonding pads UBP_HV of FIG. 13B, the lower high-voltage bonding pads 380e may correspond to the lower high-voltage bonding pads LBP_HV of FIG. 13B, and the upper dummy bonding pads 280c and the lower dummy bonding pads 380c may correspond to the dummy bonding pads BP_DM of FIG. 13B. In some embodiments, the high voltage VPP generated by the circuit element 320c, for example, the voltage generator 15, which is included in the third region 153, may be transferred to the circuit element 320a, for example, the row decoder 13a, which is included in the first region 151, through the first and second metal layers 330 and 340, the lower high-voltage bonding pads 380e, the upper high-voltage bonding pads 280e, and the third metal layer 270.

In some embodiments, the size or pitch of each of the lower high-voltage bonding pads 380e may be greater than the size or pitch of each of the lower dummy bonding pads 380c. In some embodiments, the size or pitch of each of the upper high-voltage bonding pads 280e may be greater than the size or pitch of each of the upper dummy bonding pads 280c. In some embodiments, the size or pitch of each of the lower high-voltage bonding pads 380e may be greater than the size or pitch of each of the upper high-voltage bonding pads 280e corresponding thereto. In some embodiments, the number of upper high-voltage bonding pads 280e may be greater than the number of lower high-voltage bonding pads 380e.

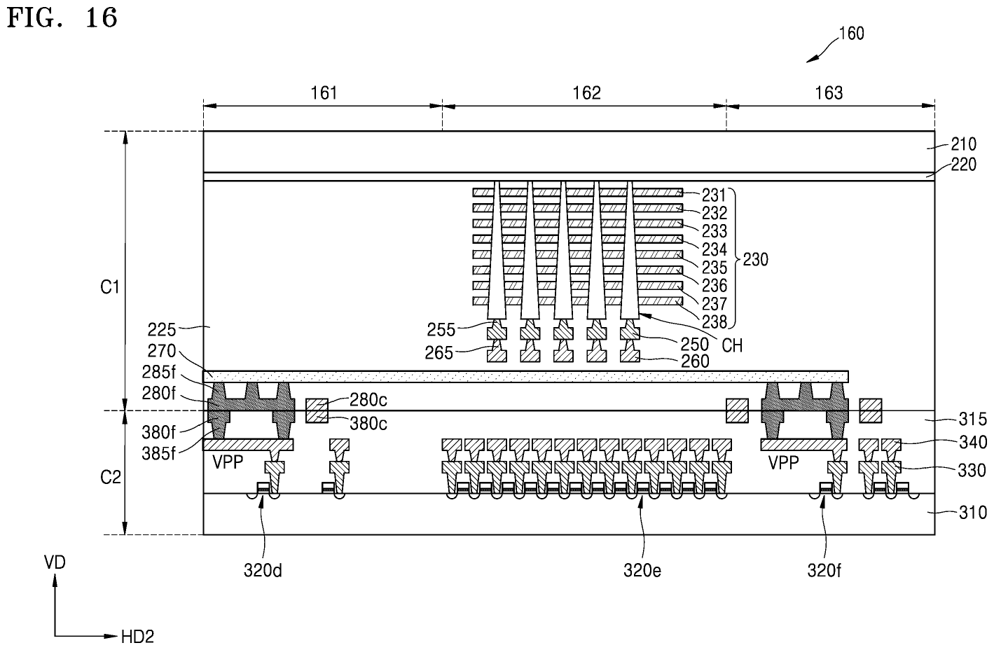

FIG. 16 is a cross-sectional view illustrating a memory device 160 according to an embodiment.

Referring together to FIGS. 10 and 16, the memory device 160 may correspond to an example of the memory device 100 of FIG. 10 and may correspond to a modified example of the memory device 140 of FIG. 14. Thus, the descriptions made above with reference to FIG. 14 may be applied to the memory device 160 of FIG. 16, and repeated descriptions thereof are omitted. The memory device 160 may include first to third regions 161 to 163. For example, the second region 162 may correspond to a certain region of the first or second memory cell array MCA1 or MCA2 of FIG. 4. As another example, the first region 161 may correspond to the third region R3 of each of the first cell region 101 and the first peripheral region 103 in FIG. 10, and the third region 163 may correspond to the third region R3 of each of the second cell region 102 and the second peripheral region 104 in FIG. 10.

The second semiconductor chip C2 may include, in the first region 161, the circuit elements 320a, the first and second metal layers 330 and 340, lower high-voltage bonding pads 380f and 385f, and the lower dummy bonding pads 380c. Alternatively or additionally, the second semiconductor chip C2 may include, in the third region 163, the circuit elements 320c, the first and second metal layers 330 and 340, the lower high-voltage bonding pads 380f and 385f, and the lower dummy bonding pads 380c. The first semiconductor chip C1 may include, in the first and third regions 161 and 163, upper high-voltage bonding pads 280f and 285f and the upper dummy bonding pads 280c. Alternatively or additionally, the first semiconductor chip C1 may include, in the second region 162, the plurality of gate electrodes 230, the plurality of channel structures CH, the first metal layer 250, and the second metal layer 260. Furthermore, the first semiconductor chip C1 may further include, in the first to third regions 161 to 163, the third metal layer 270 for connecting the upper high-voltage bonding pads 280f and 285f to each other.

In some embodiments, the upper high-voltage bonding pads 280f may correspond to the upper high-voltage bonding pads UBP_HV of FIG. 13C, the lower high-voltage bonding pads 380f may correspond to the lower high-voltage bonding pads LBP_HV of FIG. 13B, and the upper dummy bonding pads 280c and the lower dummy bonding pads 380c may correspond to the dummy bonding pads BP_DM of FIG. 13C. In some embodiments, the high voltage VPP generated by the circuit element 320c, for example, the voltage generator 15, which is included in the third region 163, may be transferred to the circuit element 320a, for example, the row decoder 13a, which is included in the first region 161, through the first and second metal layers 330 and 340, the lower high-voltage bonding pads 380f, the upper high-voltage bonding pads 280f, and the third metal layer 270.

In some embodiments, the size or pitch of each of the lower high-voltage bonding pads 380f may be greater than the size or pitch of each of the lower dummy bonding pads 380c. In some embodiments, the size or pitch of each of the upper high-voltage bonding pads 280f may be greater than the size or pitch of each of the upper dummy bonding pads 280c. In some embodiments, the size or pitch of each of the lower high-voltage bonding pads 380f may be less than the size or pitch of each of the upper high-voltage bonding pads 280f corresponding thereto. In some embodiments, the number of upper high-voltage bonding pads 280f may be less than the number of lower high-voltage bonding pads 380f.

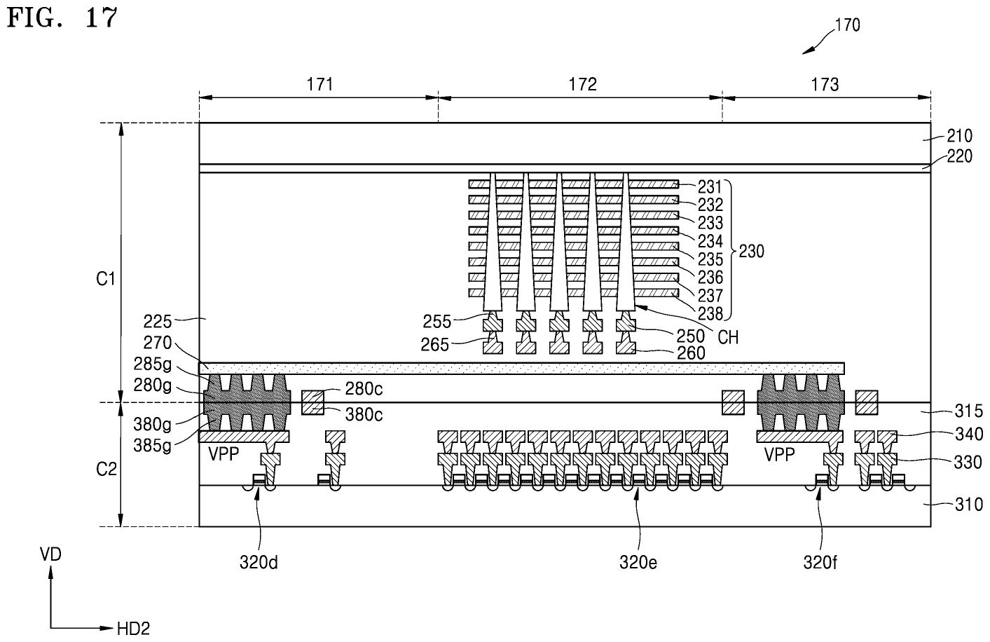

FIG. 17 is a cross-sectional view illustrating a memory device 170 according to an embodiment.

Referring together to FIGS. 10 and 17, the memory device 170 may correspond to an example of the memory device 100 of FIG. 10 and may correspond to a modified example of the memory device 140 of FIG. 14. Thus, the descriptions made above with reference to FIG. 14 may be applied to the memory device 170 of FIG. 17, and repeated descriptions thereof are omitted. The memory device 170 may include first to third regions 171 to 173. For example, the second region 172 may correspond to a certain region of the first or second memory cell array MCA1 or MCA2 of FIG. 4. As another example, the first region 171 may correspond to the third region R3 of each of the first cell region 101 and the first peripheral region 103 in FIG. 10, and the third region 173 may correspond to the third region R3 of each of the second cell region 102 and the second peripheral region 104 in FIG. 10.

The second semiconductor chip C2 may include, in the first region 171, the circuit elements 320a, the first and second metal layers 330 and 340, lower high-voltage bonding pads 380g and 385g, and the lower dummy bonding pads 380c. Alternatively or additionally, the second semiconductor chip C2 may include, in the third region 173, the circuit elements 320c, the first and second metal layers 330 and 340, the lower high-voltage bonding pads 380g and 385g, and the lower dummy bonding pads 380c. The first semiconductor chip C1 may include, in the first and third regions 171 and 173, upper high-voltage bonding pads 280g and 285g and the upper dummy bonding pads 280c. Alternatively or additionally, the first semiconductor chip C1 may include, in the second region 172, the plurality of gate electrodes 230, the plurality of channel structures CH, the first metal layer 250, and the second metal layer 260. Furthermore, the first semiconductor chip C1 may further include, in the first to third regions 171 to 173, the third metal layer 270 for connecting the upper high-voltage bonding pads 280g and 285g to each other.

In some embodiments, the upper high-voltage bonding pads 280g and the lower high-voltage bonding pads 380g may correspond to the high-voltage bonding pads BP_HV of FIG. 13D, and the upper dummy bonding pads 280c and the lower dummy bonding pads 380c may correspond to the dummy bonding pads BP_DM of FIG. 13C. In some embodiments, the high voltage VPP generated by the circuit element 320c, for example, the voltage generator 15, which is included in the third region 173, may be transferred to the circuit element 320a, for example, the row decoder 13a, which is included in the first region 171, through the first and second metal layers 330 and 340, the lower high-voltage bonding pads 380g, the upper high-voltage bonding pads 280g, and the third metal layer 270.

In some embodiments, the size or pitch of each of the lower high-voltage bonding pads 380g may be greater than the size or pitch of each of the lower dummy bonding pads 380c. In some embodiments, the size or pitch of each of the upper high-voltage bonding pads 280g may be greater than the size or pitch of each of the upper dummy bonding pads 280c. In some embodiments, the size or pitch of each of the upper high-voltage bonding pads 280g may be substantially equal to the size or pitch of each of the lower high-voltage bonding pads 380g corresponding thereto. In some embodiments, the number of upper high-voltage bonding pads 280g may be equal to the number of lower high-voltage bonding pads 380g.

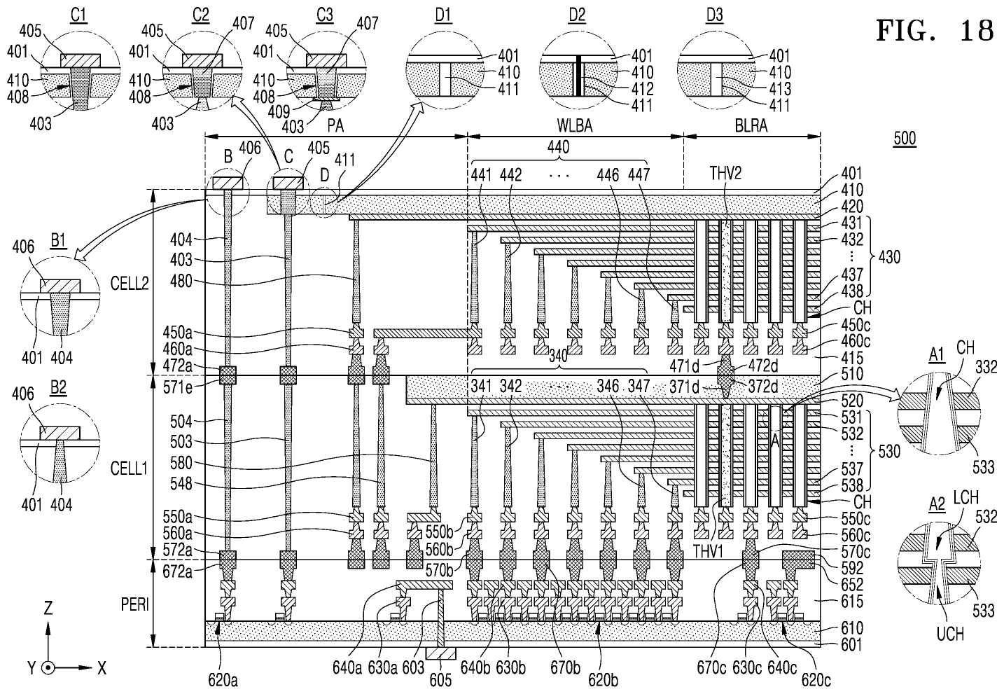

FIG. 18 is a cross-sectional view of a memory device 500 having a B-VNAND structure, according to an embodiment.

Referring to FIG. 18, the memory device 500 may have a chip-to-chip (C2C) structure. At least one upper chip including a cell region and a lower chip including a peripheral circuit region PERI may be manufactured separately, and then, the at least one upper chip and the lower chip may be connected to each other by a bonding method to realize the C2C structure. For example, the bonding method may mean a method of electrically or physically connecting a bonding metal pattern formed in an uppermost metal layer of the upper chip to a bonding metal pattern formed in an uppermost metal layer of the lower chip. As another example, in a case in which the bonding metal patterns are formed of copper (Cu), the bonding method may be a Cu—Cu bonding method. Alternatively or additionally, the bonding metal patterns may be formed of aluminum (Al) or tungsten (W).

The memory device 500 may include the at least one upper chip including the cell region. For example, as illustrated in FIG. 18, the memory device 500 may include two upper chips. However, the number of upper chips is not limited thereto. In the case in which the memory device 500 includes the two upper chips, a first upper chip including a first cell region CELL1, a second upper chip including a second cell region CELL2, and the lower chip including the peripheral circuit region PERI may be manufactured separately, and then, the first upper chip, the second upper chip, and the lower chip may be connected to each other by the bonding method to manufacture the memory device 500. The first upper chip may be turned over and then may be connected to the lower chip by the bonding method, and the second upper chip may also be turned over and then may be connected to the first upper chip by the bonding method. Hereinafter, upper and lower portions of each of the first and second upper chips will be defined based on before each of the first and second upper chips is turned over. That is, an upper portion of the lower chip may mean an upper portion defined based on a +Z-axis direction, and the upper portion of each of the first and second upper chips may mean an upper portion defined based on a −Z-axis direction in FIG. 18. However, embodiments of the present disclosure are not limited thereto. In certain embodiments, one of the first upper chip and the second upper chip may be turned over and then may be connected to a corresponding chip by the bonding method.

Each of the peripheral circuit region PERI and the first and second cell regions CELL1 and CELL2 of the memory device 500 may include an external pad bonding region PA, a word line bonding region WLBA, and a bit line bonding region BLBA.

The peripheral circuit region PERI may include a first substrate 610 and a plurality of circuit elements 620a, 620b and 620c formed on the first substrate 610. An interlayer insulating layer 615 including one or more insulating layers may be provided on the plurality of circuit elements 620a, 620b and 620c, and a plurality of metal lines electrically connected to the plurality of circuit elements 620a, 620b and 620c may be provided in the interlayer insulating layer 615. For example, the plurality of metal lines may include first metal lines 630a, 630b and 630c connected to the plurality of circuit elements 620a, 620b and 620c, and second metal lines 640a, 640b and 640c formed on the first metal lines 630a, 630b and 630c. The plurality of metal lines may be formed of at least one of various conductive materials. For example, the first metal lines 630a, 630b and 630c may be formed of tungsten having a relatively high electrical resistivity, and the second metal lines 640a, 640b and 640c may be formed of copper having a relatively low electrical resistivity.

The first metal lines 630a, 630b and 630c and the second metal lines 640a, 640b and 640c are illustrated and described in the present embodiments. However, embodiments of the present disclosure are not limited thereto. In certain embodiments, one or more additional metal lines may further be formed on the second metal lines 640a, 640b and 640c. In this case, the second metal lines 640a, 640b and 640c may be formed of aluminum, and at least some of the additional metal lines formed on the second metal lines 640a, 640b and 640c may be formed of copper having an electrical resistivity lower than that of aluminum of the second metal lines 640a, 640b and 640c.

The interlayer insulating layer 615 may be disposed on the first substrate 610 and may include an insulating material, such as silicon oxide and/or silicon nitride.

Each of the first and second cell regions CELL1 and CELL2 may include at least one memory block. The first cell region CELL1 may include a second substrate 510 and a common source line 520. A plurality of word lines 530 (e.g., 531 to 538) may be stacked on the second substrate 510 in a direction (e.g., the Z-axis direction) perpendicular to a top surface of the second substrate 510. String selection lines and a ground selection line may be disposed on and under the word lines 530, and the plurality of word lines 530 may be disposed between the string selection lines and the ground selection line. Likewise, the second cell region CELL2 may include a third substrate 410 and a common source line 420, and a plurality of word lines 430 (e.g., 431 to 438) may be stacked on the third substrate 410 in a direction (e.g., the Z-axis direction) perpendicular to a top surface of the third substrate 410. Each of the second substrate 510 and the third substrate 410 may be formed of at least one of various materials and may be, for example, a silicon substrate, a silicon-germanium substrate, a germanium substrate, or a substrate having a single-crystalline epitaxial layer grown on a single-crystalline silicon substrate. A plurality of channel structures CH may be formed in each of the first and second cell regions CELL1 and CELL2.

In some embodiments, as illustrated in a region ‘A1’, the channel structure CH may be provided in the bit line bonding region BLBA and may extend in the direction perpendicular to the top surface of the second substrate 510 to penetrate the word lines 530, the string selection lines, and the ground selection line. The channel structure CH may include a data storage layer, a channel layer, and a filling insulation layer. The channel layer may be electrically connected to a first metal line 550c and a second metal line 560c in the bit line bonding region BLBA. For example, the second metal line 560c may be a bit line and may be connected to the channel structure CH through the first metal line 550c. The bit line 560c may extend in a first direction (e.g., a Y-axis direction) parallel to the top surface of the second substrate 510.

In some embodiments, as illustrated in a region A2, the channel structure CH may include a lower channel LCH and an upper channel UCH, which are connected to each other. For example, the channel structure CH may be formed by a process of forming the lower channel LCH and a process of forming the upper channel UCH. The lower channel LCH may extend in the direction perpendicular to the top surface of the second substrate 510 to penetrate the common source line 520 and lower word lines 531 and 532. The lower channel LCH may include a data storage layer, a channel layer, and a filling insulation layer and may be connected to the upper channel UCH. The upper channel UCH may penetrate upper word lines 533 to 538. The upper channel UCH may include a data storage layer, a channel layer, and a filling insulation layer, and the channel layer of the upper channel UCH may be electrically connected to the first metal line 550c and the second metal line 560c. As a length of a channel increases, due to characteristics of manufacturing processes, it may be difficult to form a channel having a substantially uniform width. The memory device 500, according to some embodiments, may include a channel having improved width uniformity due to the lower channel LCH and the upper channel UCH, which are formed by the processes performed sequentially.

In the case in which the channel structure CH includes the lower channel LCH and the upper channel UCH as illustrated in the region A2, a word line located near to a boundary between the lower channel LCH and the upper channel UCH may be a dummy word line. For example, the word lines 532 and 533 adjacent to the boundary between the lower channel LCH and the upper channel UCH may be the dummy word lines. In this case, data may not be stored in memory cells connected to the dummy word line. Alternatively or additionally, the number of pages corresponding to the memory cells connected to the dummy word line may be less than the number of pages corresponding to the memory cells connected to a general word line. A level of a voltage applied to the dummy word line may be different from a level of a voltage applied to the general word line, and thus it is possible to reduce an influence of a non-uniform channel width between the lower and upper channels LCH and UCH on an operation of the memory device.

Meanwhile, the number of the lower word lines 531 and 532 penetrated by the lower channel LCH is less than the number of the upper word lines 533 to 538 penetrated by the upper channel UCH in the region A2. However, embodiments of the present disclosure are not limited thereto. In certain embodiments, the number of lower word lines penetrated by the lower channel LCH may be equal to or more than the number of upper word lines penetrated by the upper channel UCH. Alternatively or additionally, structural features and connection relation of the channel structure CH disposed in the second cell region CELL2 may be substantially the same as those of the channel structure CH disposed in the first cell region CELL1.

In the bit line bonding region BLBA, a first through-electrode THV1 may be provided in the first cell region CELL1, and a second through-electrode THV2 may be provided in the second cell region CELL2. As illustrated in FIG. 18, the first through-electrode THV1 may penetrate the common source line 520 and the plurality of word lines 530. In certain embodiments, the first through-electrode THV1 may further penetrate the second substrate 510. The first through-electrode THV1 may include a conductive material. Alternatively or additionally, the first through-electrode THV1 may include a conductive material surrounded by an insulating material. The second through-electrode THV2 may have the same shape and structure as the first through-electrode THV1.

In some embodiments, the first through-electrode THV1 and the second through-electrode THV2 may be electrically connected to each other through a first through-metal pattern 572d and a second through-metal pattern 472d. The first through-metal pattern 572d may be formed at a bottom end of the first upper chip including the first cell region CELL1, and the second through-metal pattern 472d may be formed at a top end of the second upper chip including the second cell region CELL2. The first through-electrode THV1 may be electrically connected to the first metal line 550c and the second metal line 560c. A lower via 571d may be formed between the first through-electrode THV1 and the first through-metal pattern 572d, and an upper via 471d may be formed between the second through-electrode THV2 and the second through-metal pattern 472d. The first through-metal pattern 572d and the second through-metal pattern 472d may be connected to each other by the bonding method.

Alternatively or additionally, in the bit line bonding region BLBA, an upper metal pattern 652 may be formed in an uppermost metal layer of the peripheral circuit region PERI, and an upper metal pattern 592 having the same shape as the upper metal pattern 652 may be formed in an uppermost metal layer of the first cell region CELL1. The upper metal pattern 592 of the first cell region CELL1 and the upper metal pattern 652 of the peripheral circuit region PERI may be electrically connected to each other by the bonding method. In the bit line bonding region BLBA, the bit line 560c may be electrically connected to a page buffer included in the peripheral circuit region PERI. For example, some of the circuit elements 620c of the peripheral circuit region PERI may constitute the page buffer, and the bit line 560c may be electrically connected to the circuit elements 620c constituting the page buffer through an upper bonding metal pattern 570c of the first cell region CELL1 and an upper bonding metal pattern 670c of the peripheral circuit region PERI.

Continuing to refer to FIG. 18, in the word line bonding region WLBA, the word lines 530 of the first cell region CELL1 may extend in a second direction (e.g., an X-axis direction) parallel to the top surface of the second substrate 510 and may be connected to a plurality of cell contact plugs 540 (e.g., 541 to 547). First metal lines 550b and second metal lines 560b may be sequentially connected onto the cell contact plugs 540 connected to the word lines 530. In the word line bonding region WLBA, the cell contact plugs 540 may be connected to the peripheral circuit region PERI through upper bonding metal patterns 570b of the first cell region CELL1 and upper bonding metal patterns 670b of the peripheral circuit region PERI.

The cell contact plugs 540 may be electrically connected to a row decoder included in the peripheral circuit region PERI. For example, some of the circuit elements 620b of the peripheral circuit region PERI may constitute the row decoder, and the cell contact plugs 540 may be electrically connected to the circuit elements 620b constituting the row decoder through the upper bonding metal patterns 570b of the first cell region CELL1 and the upper bonding metal patterns 670b of the peripheral circuit region PERI. In some embodiments, an operating voltage of the circuit elements 620b constituting the row decoder may be different from an operating voltage of the circuit elements 620c constituting the page buffer. For example, the operating voltage of the circuit elements 620c constituting the page buffer may be greater than the operating voltage of the circuit elements 620b constituting the row decoder.

Likewise, in the word line bonding region WLBA, the word lines 430 of the second cell region CELL2 may extend in the second direction (e.g., the X-axis direction) parallel to the top surface of the third substrate 410 and may be connected to a plurality of cell contact plugs 440 (e.g., 441 to 447). The cell contact plugs 440 may be connected to the peripheral circuit region PERI through an upper metal pattern of the second cell region CELL2 and lower and upper metal patterns and a cell contact plug 548 of the first cell region CELL1.

In the word line bonding region WLBA, the upper bonding metal patterns 570b may be formed in the first cell region CELL1, and the upper bonding metal patterns 670b may be formed in the peripheral circuit region PERI. The upper bonding metal patterns 570b of the first cell region CELL1 and the upper bonding metal patterns 670b of the peripheral circuit region PERI may be electrically connected to each other by the bonding method. The upper bonding metal patterns 570b and the upper bonding metal patterns 670b may be formed of aluminum, copper, or tungsten.

In the external pad bonding region PA, a lower metal pattern 571e may be formed in a lower portion of the first cell region CELL1, and an upper metal pattern 472a may be formed in an upper portion of the second cell region CELL2. The lower metal pattern 571e of the first cell region CELL1 and the upper metal pattern 472a of the second cell region CELL2 may be connected to each other by the bonding method in the external pad bonding region PA. Likewise, an upper metal pattern 572a may be formed in an upper portion of the first cell region CELL1, and an upper metal pattern 672a may be formed in an upper portion of the peripheral circuit region PERI. The upper metal pattern 572a of the first cell region CELL1 and the upper metal pattern 672a of the peripheral circuit region PERI may be connected to each other by the bonding method.

Common source line contact plugs 580 and 480 may be disposed in the external pad bonding region PA. The common source line contact plugs 580 and 480 may be formed of a conductive material, such as a metal, a metal compound, and/or doped polysilicon. The common source line contact plug 580 of the first cell region CELL1 may be electrically connected to the common source line 520, and the common source line contact plug 480 of the second cell region CELL2 may be electrically connected to the common source line 420. A first metal line 550a and a second metal line 560a may be sequentially stacked on the common source line contact plug 580 of the first cell region CELL1, and a first metal line 450a and a second metal line 460a may be sequentially stacked on the common source line contact plug 480 of the second cell region CELL2.

Input/output pads 605, 405 and 406 may be disposed in the external pad bonding region PA. Referring to FIG. 18, a lower insulating layer 601 may cover a bottom surface of the first substrate 610, and the first input/output pad 605 may be formed on the lower insulating layer 601. The first input/output pad 605 may be connected to at least one of a plurality of the circuit elements 620a disposed in the peripheral circuit region PERI through a first input/output contact plug 603 and may be separated from the first substrate 610 by the lower insulating layer 601. Alternatively or additionally, a side insulating layer may be disposed between the first input/output contact plug 603 and the first substrate 610 to electrically isolate the first input/output contact plug 603 from the first substrate 610.

An upper insulating layer 401 covering a top surface of the third substrate 410 may be formed on the third substrate 410. The second input/output pad 405 and/or the third input/output pad 406 may be disposed on the upper insulating layer 401. The second input/output pad 405 may be connected to at least one of the plurality of circuit elements 620a disposed in the peripheral circuit region PERI through second input/output contact plugs 403 and 503, and the third input/output pad 406 may be connected to at least one of the plurality of circuit elements 620a disposed in the peripheral circuit region PERI through third input/output contact plugs 404 and 504.

In some embodiments, the third substrate 410 may not be disposed in a region in which the input/output contact plug is disposed. For example, as illustrated in a region B, the third input/output contact plug 404 may be separated from the third substrate 410 in a direction parallel to the top surface of the third substrate 410 and may penetrate an interlayer insulating layer 415 of the second cell region CELL2 so as to be connected to the third input/output pad 406. In this case, the third input/output contact plug 404 may be formed by at least one of various processes.

In some embodiments, as illustrated in a region B1, the third input/output contact plug 404 may extend in a third direction (e.g., the Z-axis direction), and a diameter of the third input/output contact plug 404 may progressively increase toward the upper insulating layer 401. In other words, a diameter of the channel structure CH described in the region A1 may progressively decrease toward the upper insulating layer 401, but the diameter of the third input/output contact plug 404 may progressively increase toward the upper insulating layer 401. For example, the third input/output contact plug 404 may be formed after the second cell region CELL2 and the first cell region CELL1 are bonded to each other by the bonding method.

In certain embodiments, as illustrated in a region B2, the third input/output contact plug 404 may extend in the third direction (e.g., the Z-axis direction), and a diameter of the third input/output contact plug 404 may progressively decrease toward the upper insulating layer 401. That is, like the channel structure CH, the diameter of the third input/output contact plug 404 may progressively decrease toward the upper insulating layer 401. For example, the third input/output contact plug 404 may be formed together with the cell contact plugs 440 before the second cell region CELL2 and the first cell region CELL1 are bonded to each other.

In certain embodiments, the input/output contact plug may overlap with the third substrate 410. For example, as illustrated in a region C, the second input/output contact plug 403 may penetrate the interlayer insulating layer 415 of the second cell region CELL2 in the third direction (e.g., the Z-axis direction) and may be electrically connected to the second input/output pad 405 through the third substrate 410. In this case, a connection structure of the second input/output contact plug 403 and the second input/output pad 405 may be realized by various methods.

In some embodiments, as illustrated in a region C1, an opening 408 may be formed to penetrate the third substrate 410, and the second input/output contact plug 403 may be connected directly to the second input/output pad 405 through the opening 408 formed in the third substrate 410. In this case, as illustrated in the region C1, a diameter of the second input/output contact plug 403 may progressively increase toward the second input/output pad 405. However, embodiments of the present disclosure are not limited thereto, and in certain embodiments, the diameter of the second input/output contact plug 403 may progressively decrease toward the second input/output pad 405.

In certain embodiments, as illustrated in a region C2, the opening 408 penetrating the third substrate 410 may be formed, and a contact 407 may be formed in the opening 408. An end of the contact 407 may be connected to the second input/output pad 405, and another end of the contact 407 may be connected to the second input/output contact plug 403. Thus, the second input/output contact plug 403 may be electrically connected to the second input/output pad 405 through the contact 407 in the opening 408. In this case, as illustrated in the region C2, a diameter of the contact 407 may progressively increase toward the second input/output pad 405, and a diameter of the second input/output contact plug 403 may progressively decrease toward the second input/output pad 405. For example, the second input/output contact plug 403 may be formed together with the cell contact plugs 440 before the second cell region CELL2 and the first cell region CELL1 are bonded to each other, and the contact 407 may be formed after the second cell region CELL2 and the first cell region CELL1 are bonded to each other.

In certain embodiments, as illustrated in a region C3, a stopper 409 may further be formed on a bottom end of the opening 408 of the third substrate 410, as compared with the embodiments of the region C2. The stopper 409 may be a metal line formed in the same layer as the common source line 420. Alternatively or additionally, the stopper 409 may be a metal line formed in the same layer as at least one of the word lines 430. The second input/output contact plug 403 may be electrically connected to the second input/output pad 405 through the contact 407 and the stopper 409.

Like the second and third input/output contact plugs 403 and 404 of the second cell region CELL2, a diameter of each of the second and third input/output contact plugs 503 and 504 of the first cell region CELL1 may progressively decrease toward the lower metal pattern 571e or may progressively increase toward the lower metal pattern 571e.

Meanwhile, in some embodiments, a slit 411 may be formed in the third substrate 410. For example, the slit 411 may be formed at a certain position of the external pad bonding region PA. For example, as illustrated in a region D, the slit 411 may be located between the second input/output pad 405 and the cell contact plugs 440 when viewed in a plan view. Alternatively, the second input/output pad 405 may be located between the slit 411 and the cell contact plugs 440 when viewed in a plan view.

In some embodiments, as illustrated in a region D1, the slit 411 may be formed to penetrate the third substrate 410. For example, the slit 411 may be used to prevent the third substrate 410 from being finely cracked when the opening 408 is formed. However, embodiments of the present disclosure are not limited thereto, and in certain embodiments, the slit 411 may be formed to have a depth ranging from about 60% to about 70% of a thickness of the third substrate 410.

In certain embodiments, as illustrated in a region D2, a conductive material 412 may be formed in the slit 411. For example, the conductive material 412 may be used to discharge a leakage current occurring in driving of the circuit elements in the external pad bonding region PA to the outside. In this case, the conductive material 412 may be connected to an external ground line.

In certain embodiments, as illustrated in a region D3, an insulating material 413 may be formed in the slit 411. For example, the insulating material 413 may be used to electrically isolate the second input/output pad 405 and the second input/output contact plug 403 disposed in the external pad bonding region PA from the word line bonding region WLBA. Since the insulating material 413 is formed in the slit 411, it is possible to prevent a voltage provided through the second input/output pad 405 from affecting a metal layer disposed on the third substrate 410 in the word line bonding region WLBA.

Meanwhile, in certain embodiments, the first to third input/output pads 605, 405 and 406 may be selectively formed. For example, the memory device 500 may be realized to include only the first input/output pad 605 disposed on the first substrate 610, to include only the second input/output pad 405 disposed on the third substrate 410, or to include only the third input/output pad 406 disposed on the upper insulating layer 401.

In some embodiments, at least one of the second substrate 510 of the first cell region CELL1 or the third substrate 410 of the second cell region CELL2 may be used as a sacrificial substrate and may be completely or partially removed before or after a bonding process. An additional layer may be stacked after the removal of the substrate. For example, the second substrate 510 of the first cell region CELL1 may be removed before or after the bonding process of the peripheral circuit region PERI and the first cell region CELL1, and then, an insulating layer covering a top surface of the common source line 520 or a conductive layer for connection may be formed. Likewise, the third substrate 410 of the second cell region CELL2 may be removed before or after the bonding process of the first cell region CELL1 and the second cell region CELL2, and then, the upper insulating layer 401 covering a top surface of the common source line 420 or a conductive layer for connection may be formed.

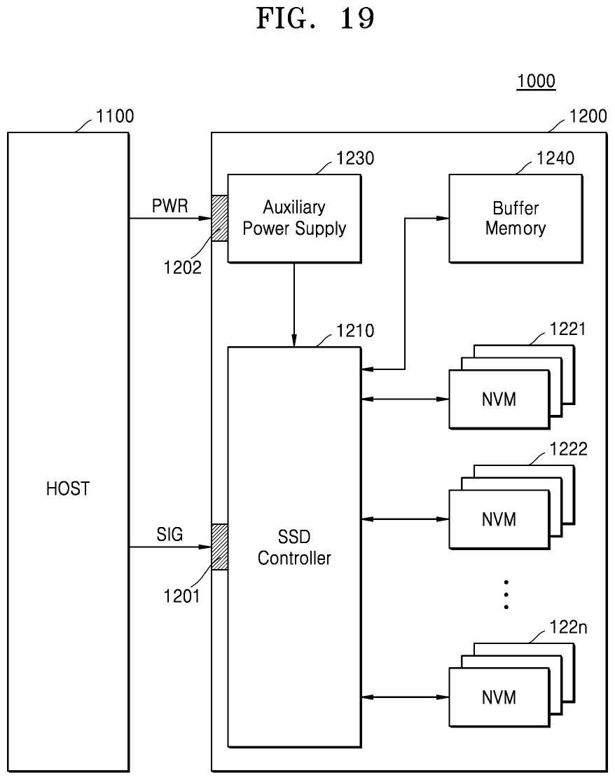

FIG. 19 is a block diagram illustrating an SSD system 1000, to which a memory device according to an embodiment is applied.

Referring to FIG. 19, the SSD system 1000 may include a host 1100 and an SSD 1200. The SSD 1200 exchanges signals with the host 1100 through a signal connector and receives power as input through a power connector. The SSD 1200 may include an SSD controller 1210, an auxiliary power supply 1230, and memory devices 1221, 1222, and 122n. Each of the memory devices 1221, 1222, and 122n may include a vertically stacked NAND flash memory device. Here, the SSD 1200 may be implemented by using the embodiments described above with reference to FIGS. 1 to 18.

As described above, example embodiments have been disclosed in the present disclosure. Although the embodiments have been described using certain terms herein, this is used for the purpose of explaining the technical idea of the present disclosure, not to be used to limit the scope of the present disclosure described in the claims. Therefore, it will be understood by those skilled in the art that various modifications and other equivalent embodiments are possible therefrom. Thus, the true technical protection scope of the present disclosure should be defined by the technical idea of the claims.

While the present disclosure has been particularly shown and described with reference to embodiments thereof, it will be understood that various changes in form and details may be made therein without departing from the spirit and scope of the following claims.

What is claimed is:

1. A non-volatile memory device comprising:
a first semiconductor chip, which comprises a memory cell array, a first upper bonding pad, a second upper bonding pad, and an upper dummy bonding pad between the first upper bonding pad and the second upper bonding pad; and
a second semiconductor chip, which is coupled to the first semiconductor chip in a vertical direction, and comprises a first lower bonding pad corresponding to the first upper bonding pad, a second lower bonding pad corresponding to the second upper bonding pad, a lower dummy bonding pad corresponding to the upper dummy bonding pad, and a peripheral circuit coupled to the first lower bonding pad and the second lower bonding pad,
wherein the first upper bonding pad and the first lower bonding pad are configured to transfer a first voltage between the first semiconductor chip and the second semiconductor chip, and
wherein the second upper bonding pad and the second lower bonding pad are configured to transfer a second voltage between the first semiconductor chip and the second semiconductor chip, a second level of the second voltage being higher than a first level of the first voltage.

2. The non-volatile memory device of claim 1, wherein the first semiconductor chip further comprises a plurality of gate electrodes coupled to the memory cell array,
wherein the first upper bonding pad is coupled to a first gate electrode from among the plurality of gate electrodes,
wherein the second upper bonding pad is coupled to a second gate electrode from among the plurality of gate electrodes, and
wherein the memory cell array is coupled to a row decoder in the peripheral circuit through the first upper bonding pad, the second upper bonding pad, the first lower bonding pad, and the second lower bonding pad.

3. The non-volatile memory device of claim 2, wherein the first gate electrode comprises a ground select line or a string select line, and the second gate electrode comprises a word line or a dummy word line.

4. The non-volatile memory device of claim 1, wherein the second upper bonding pad has a first width in a first direction,
wherein the second lower bonding pad has the first width in the first direction, and
wherein the second lower bonding pad is coupled to the second upper bonding pad in a bonding manner.

5. The non-volatile memory device of claim 1, wherein the second upper bonding pad has a first width in a first direction,
wherein the second lower bonding pad comprises a plurality of lower bonding pads arranged in a line in the first direction, each of the plurality of lower bonding pads having a second width in the first direction, the second width being less than the first width, and
wherein the plurality of lower bonding pads are coupled to the second upper bonding pad in a bonding manner.

6. The non-volatile memory device of claim 1, wherein the second upper bonding pad comprises a plurality of upper bonding pads arranged in a line in the first direction, each of the plurality of upper bonding pads having a first width in the first direction,
wherein the second lower bonding pad has a second width in the first direction, the second width being greater than the first width, and
wherein the plurality of upper bonding pads are coupled to the second lower bonding pad in a bonding manner.

7. A non-volatile memory device, comprising:
a first semiconductor chip, which comprises a memory cell array, a first upper bonding pad having a first width in a first direction, and a second upper bonding pad having a second width in the first direction, the second width being greater than the first width; and
a second semiconductor chip, which is coupled to the first semiconductor chip in a vertical direction and comprises a first lower bonding pad corresponding to the first upper bonding pad, a second lower bonding pad corresponding to the second upper bonding pad, and a peripheral circuit coupled to the first lower bonding pad and the second lower bonding pad,
wherein the first upper bonding pad and the first lower bonding pad are configured to transfer a first voltage between the first semiconductor chip and the second semiconductor chip, and
wherein the second upper bonding pad and the second lower bonding pad are configured to transfer a second voltage between the first semiconductor chip and the second semiconductor chip, a second level of the second voltage being higher than a first level of the first voltage.

8. The non-volatile memory device of claim 7, wherein the second lower bonding pad has the second width in the first direction, and
wherein the second lower bonding pad is coupled to the second upper bonding pad in a bonding manner.

9. The non-volatile memory device of claim 7, wherein the second lower bonding pad comprises a plurality of lower bonding pads arranged in a line in the first direction, each of the plurality of lower bonding pads having a third width in the first direction, the third width being less than the second width, and
wherein the plurality of lower bonding pads are coupled to the second upper bonding pad in a bonding manner.

10. The non-volatile memory device of claim 7, wherein the second upper bonding pad comprises a plurality of upper bonding pads arranged in a line in the first direction,
wherein the second lower bonding pad has a fourth width in the first direction, the fourth width being greater than the second width, and
wherein the plurality of upper bonding pads are coupled to the second lower bonding pad in a bonding manner.

11. The non-volatile memory device of claim 7, wherein the first semiconductor chip further comprises an upper dummy bonding pad disposed on one surface of the first semiconductor chip adjacent to the second upper bonding pad, and
wherein the second semiconductor chip further comprises a lower dummy bonding pad corresponding to the upper dummy bonding pad.

12. The non-volatile memory device of claim 7, wherein the first semiconductor chip further comprises a plurality of gate electrodes coupled to the memory cell array,
wherein the first upper bonding pad is coupled to a first gate electrode from among the plurality of gate electrodes,
wherein the second upper bonding pad is coupled to a second gate electrode from among the plurality of gate electrodes, and
wherein the memory cell array is coupled to a row decoder in the peripheral circuit through the first upper bonding pad, the second upper bonding pad, the first lower bonding pad, and the second lower bonding pad.

13. The non-volatile memory device of claim 12, wherein the first gate electrode comprises a ground select line or a string select line, and the second gate electrode comprises a word line or a dummy word line.

14. The non-volatile memory device of claim 12, wherein the first semiconductor chip further comprises a third upper bonding pad, which is coupled to a third gate electrode from among the plurality of gate electrodes and has the second width in the first direction,
wherein the second semiconductor chip further comprises a third lower bonding pad corresponding to the third upper bonding pad, and
wherein the memory cell array is configured to receive a third voltage from the row decoder through the third upper bonding pad and the third lower bonding pad, a third level of the third voltage being higher than the first level of the first voltage.

15. The non-volatile memory device of claim 7, wherein the first semiconductor chip further comprises a third upper bonding pad, which has a third width in the first direction, and a metal layer configured to connect the second upper bonding pad to the third upper bonding pad,
wherein the second semiconductor chip further comprises a third lower bonding pad corresponding to the third upper bonding pad,
wherein the peripheral circuit comprises a first peripheral circuit, which is coupled to the second lower bonding pad, and a second peripheral circuit, which is coupled to the third lower bonding pad, and
wherein the first peripheral circuit is configured to receive the second voltage from the second peripheral circuit through the second upper bonding pad, the third upper bonding pad, the second lower bonding pad, the third lower bonding pad, and the metal layer.

16. A non-volatile memory device comprising:
a first semiconductor chip comprising a first cell region and a second cell region that are adjacent to each other in a first direction, the first cell region comprising a first memory cell array, a first upper bonding pad having a first width in the first direction, and a second upper bonding pad having a second width in the first direction that is greater than the first width of the first upper bonding pad, and the second cell region comprising a second memory cell array and a third upper bonding pad; and
a second semiconductor chip, which is coupled to the first semiconductor chip in a vertical direction and comprises a first peripheral region and a second peripheral region, the first peripheral region comprising a first lower bonding pad corresponding to the first upper bonding pad, a second lower bonding pad corresponding to the second upper bonding pad, and a first peripheral circuit coupled to the first lower bonding pad and the second lower bonding pad, and the second peripheral region comprising a third lower bonding pad corresponding to the third upper bonding pad and a second peripheral circuit coupled to the third lower bonding pad,
wherein the first semiconductor chip further comprises a metal layer connecting the second upper bonding pad to the third upper bonding pad,
the first memory cell array is configured to receive a first voltage from the first peripheral circuit through the first upper bonding pad and the first lower bonding pad, and
wherein the first peripheral circuit is configured to receive a second voltage from the second peripheral circuit through the second upper bonding pad, the third upper bonding pad, the second lower bonding pad, the third lower bonding pad, and the metal layer, a second level of the second voltage being higher voltage level than a first level of the first voltage.

17. The non-volatile memory device of claim 16, wherein the second lower bonding pad has the second width in the first direction, and
wherein the second lower bonding pad is coupled to the second upper bonding pad in a bonding manner.

18. The non-volatile memory device of claim 16, wherein the second lower bonding pad comprises a plurality of lower bonding pads arranged in a line in the first direction, each of the plurality of lower bonding pads having a third width in the first direction, the third width being less than the second width, and
wherein the plurality of lower bonding pads are coupled to the second upper bonding pad in a bonding manner.

19. The non-volatile memory device of claim 16, wherein the second upper bonding pad comprises a plurality of upper bonding pads arranged in a line in the first direction,
wherein the second lower bonding pad has a fourth width in the first direction, the fourth width being greater than the second width, and
wherein the plurality of upper bonding pads are coupled to the second lower bonding pad in a bonding manner.

20. The non-volatile memory device of claim 16, wherein the first semiconductor chip further comprises an upper dummy bonding pad disposed on one surface of the first semiconductor chip adjacent to the second upper bonding pad, and
wherein the second semiconductor chip further comprises a lower dummy bonding pad corresponding to the upper dummy bonding pad.
